(19) United States
(12) Patent Application Publication
(10) Pub. No.: US 2018/0083222 A1
(43) Pub. Date: Mar. 22, 2018

(54) Optoelectronic component and method for producing an optoelectronic component

(71) Applicant: OSRAM OLED GmbH, Regensburg (DE)

(72) Inventors: Thomas Wehlus, Lappersdorf (DE); Nina Riegel, Tegernheim (DE); Erwin Lang, Regensburg (DE); Evelyn Trummer-Sailer, Mintraching (DE); Arne Fleissner, Regensburg (DE); Daniel Riedel, Regensburg (DE); Johannes Rosenberger, Regensburg (DE); Silke Scharner, Regensburg (DE)

(21) Appl. No.: 15/558,593

(22) PCT Filed: Mar. 15, 2016
(86) PCT No.: PCT/EP2016/055553

§ 371 Date: Sep. 15, 2017

(30) Foreign Application Priority Data
Mar. 16, 2015 (DE) 10 2015 103 796.3

(51) Int. Cl. H01L 51/52; H01L 27/32; H01L 51/56

(52) U.S. Cl. CPC H01L 51/5253; H01L 51/56; H01L 27/3213; H01L 51/5203

(57) ABSTRACT

According to the present disclosure, a method for producing an optoelectronic component is provided. The method includes forming an optically functional layer structure in accordance with at least one part of a geometric network of a body, and bending the part of the geometric network in the at least one desired bending region, such that at least one part of the body is formed. The part of the geometric network includes at least one desired bending region.

### RELATED APPLICATIONS

The present application is a national stage entry according to 35 U.S.C. § 371 of PCT application No.: PCT/EP2016/055553 filed on Mar. 15, 2016, which claims priority from German application No.: 10 2015 103 796.3 filed on Mar. 16, 2015, and is incorporated herein by reference in its entirety.

### TECHNICAL FIELD

The present disclosure relates to an optoelectronic component and to a method for producing an optoelectronic component.

### BACKGROUND

In general, optoelectronic components can be used for a wide range of applications in which the generation of light is required. By way of example, optoelectronic components are used for displaying information (e.g. in displays, in advertising panels or in mobile radio devices) and/or for illuminating objects or spatial regions, e.g. in the form of planar illumination modules. Such optoelectronic components may be based on the principle of electroluminescence, which makes it possible to convert electrical energy into light with high efficiency. By way of example, said optoelectronic components may include one or a plurality of optically functional layers, e.g. in the form of organic light-emitting diodes (OLED) or inorganic light-emitting diodes (LED), which make it possible to generate and to emit colored light in the form of patterns or with a specific color valence.

Optoelectronic components (e.g. OLED displays) are conventionally formed only as two-dimensional (2D), that is to say planar (i.e. as 2D components), or two-and-a-half-dimensional (2.5D), i.e. as 2.5D components. 2.5D denotes optoelectronic 2D components having flexible substrates which can be bent to a certain extent, such that curved optoelectronic components can be shaped therefrom.

Optoelectronic components on arbitrarily shaped substrates having three-dimensional surfaces (3D surfaces) can be realized only with difficulty in a conventional way. The shape of the 3D surface adversely affects a homogenous deposition of the optically functional layers (e.g. organic layers) thereon, e.g. on uneven substrates.

For powerful optoelectronic components, said layers are applied in layer stacks by means of physical vapor deposition. This deposition is among the so-called direct coating methods (line-of-sight methods); that is to say that in these methods material to be deposited propagates as material vapor only along a free rectilinear path. Direct coating methods enable whole-area coatings for planar (and to a limited extent also for slightly curved) substrates. These methods are unsuitable for coating the surface of a complex 3D object (e.g. having cutouts, through openings and projections), however, since uncoated regions remain as a result of shading.

However, for the functionality of the optoelectronic components it is important that the optically functional layers are applied to the substrate in an accurate and defined thickness, since otherwise the performance of the optoelectronic components is adversely affected. In particular, lateral layer thickness gradients lead to undesired luminance gradients. Therefore, conventional methods are not suitable for producing optoelectronic components on 3D surfaces even if the abovementioned shading of partial regions of 3D surfaces is avoided, since even a different angular position of the partial regions relative to the coating source leads to layer thickness gradients.

Therefore, three-dimensional optoelectronic components are conventionally manufactured by joining together a plurality of optoelectronic 2D components (i.e. planar luminous surfaces) to form 3D bodies. By way of example, a cube is created from square optoelectronic 2D components that respectively form a side face of the cube. In this case, however, non-luminous marginal regions corresponding to the margins of the optoelectronic 2D components remain at the edges of the 3D body. In the case of spheres, conventionally recourse is likewise had to a multiplicity of small optoelectronic 2D components which are joined together on the surface of the sphere. In this case, however, visible edges and gaps arise in the luminous surface.

If the intention is to reduce the non-luminous marginal regions at the edges, the optically functional layers conventionally have to extend over the edges of the 3D body, which are limited in their maximum bending radius, however, since otherwise they break and fail. In the case of 3D bodies, therefore, it is necessary to accept visibly rounded edges in order to avoid non-luminous regions at the edges. In other words, angular 3D bodies can conventionally only be joined together from planar sheetlike optoelectronic components.

In addition, as a result of the limited bending radius, gaps arise between luminous surfaces which adjoin a corner. Illustratively, the luminous surfaces gape open at the corners of the 3D body and likewise lead to non-luminous marginal regions.

### SUMMARY

In accordance with various embodiments, a simplified method for producing three-dimensional optoelectronic components is provided. This method requires fewer production steps and simplifies the construction of the three-dimensional optoelectronic components (optoelectronic 3D components), which saves production costs. By way of example, it is possible to dispense with a method step for interconnecting the luminous surfaces.

Furthermore, in accordance with various embodiments, non-luminous marginal regions at the edges of the three-dimensional optoelectronic components and/or gaps between the luminous surfaces are reduced. A more homogenous light distribution is achieved as a result, such that the impression of a seamlessly luminous 3D body is more realistic. This makes it possible to dispense with complex method steps which improve the light distribution.

Furthermore, in accordance with various embodiments, an optoelectronic 3D component is provided which is able to map a 3D body more exactly, i.e. which models the contour of the 3D body more exactly. It is thus possible for example to model smaller 3D bodies or 3D bodies having greatly fragmented surfaces.

In accordance with various embodiments, a method for producing an optoelectronic component includes the following: forming an optically functional layer structure in accordance with at least one part (i.e. one part or a plurality of parts) of a geometric network of a body (e.g. in accordance with a complete geometric network of the body), wherein the part of the geometric network includes at least one desired bending region; bending the part of the geometric network (e.g. the optically functional layer structure) in the at least one desired bending region, such that at least one part of the body is formed.

A desired bending region can be understood as a region of the geometric network (also referred to as body network or as unfolding of a body) at which two adjacent outer surfaces of the body adjoin one another. Illustratively, a desired bending region forms an edge of the body. If the geometric network is deformed, e.g. bent, in the desired bending regions thereof, the body can be formed from the geometric network. In accordance with various embodiments, bending the part of the geometric network can be effected in at least the plurality of desired bending regions, such that at least one part of the body is formed.

The body can have for example the shape of an ellipsoid or of a polygon. Alternatively or additionally, the body can be composed of one or a plurality of ellipsoids and/or of one or a plurality of polygons.

Alternatively or additionally, the carrier is plate-shaped.

In accordance with various embodiments, the optically functional layer structure can be formed as a continuous optically functional layer structure.

In accordance with various embodiments, the optically functional layer structure can be formed on a continuous elastic carrier.

In accordance with various embodiments, the optically functional layer structure can be formed in accordance with at least one part of a geometric network of a body on or above a carrier (can also be referred to as a substrate). The carrier can be formed for example in accordance with the part of the geometric network of the body. Illustratively, the carrier can have the shape of the geometric network.

Alternatively or additionally, the carrier can have an arbitrary shape. In this case, the optically functional layer structure can be formed in accordance with at least one part of a geometric network of a body on or above at least one section of a carrier. Afterward, the carrier can be severed at least partly along a path in accordance with the part of the geometric network, wherein the path surrounds the part of the geometric network. Illustratively, the section of the carrier can be separated from the carrier in accordance with the part of the geometric network. The section of the carrier can likewise be referred to as a carrier.

In accordance with various embodiments, the part of the geometric network can be bent in such a way that at least two marginal regions of the part of the geometric network which do not have a shared desired bending region are joined together, such that they adjoin one another. Illustratively, as a result of the bending, parts of the geometric network not previously connected to one another are joined together and form a joining region of the optoelectronic component.

In accordance with various embodiments, the part of the geometric network can be bent in such a way that the two marginal regions of the part of the geometric network joined together form an edge of the body. In other words, the joining region can form an edge of the body.

In accordance with various embodiments, furthermore the part of the geometric network alongside the at least one desired bending region can be bent in such a way that at least one curved outer surface, e.g. a side surface, of the part of the body is formed.

In accordance with various embodiments, the method can furthermore include: forming a metallization layer which electrically contacts the optically functional layer structure and which has exposed contact regions; and forming an encapsulation (cf. FIG. 15C and FIG. 15D) above the optically functional layer structure.

In accordance with various embodiments, forming the optically functional layer structure can be effected in such a way that the optically functional layer structure is cut out along the at least one desired bending region, such that the optically functional layer structure has a through opening above at least the one desired bending region.

Alternatively or additionally, the metallization layer and/or the encapsulation can extend partly or completely over the desired bending regions of the part of the geometric network. To that end, the metallization layer and/or the encapsulation can be elastic, e.g. spring-elastically, i.e. reversibly, deformable, wherein a deformation creates a restoring force that counteracts the deformation. Alternatively or additionally, the metallization layer and/or the encapsulation can be ductilely deformable.

In accordance with various embodiments, the optically functional layer structure can be cut out by a part of the optically functional layer structure above the at least one desired bending region being removed. In other words, a cutout can be formed in the optically functional layer structure. Illustratively, by cutting out the optically functional layer structure, it is possible to form individual optically functional layer structure segments arranged at a distance from one another (also referred to as optoelectronic component units). The layer structure segments (also referred to as luminous areas) can be assigned to individual segments (also referred to as tiles) of the part of the geometric network which delimit the body in the bent state of the part of the geometric network. By way of example, a respective tile can be assigned to an outer surface of the body, for example a base surface, side surface or top surface.

In accordance with various embodiments, the at least one a plurality of desired bending region can be bent in such a way that it forms an edge of the part of the body.

In accordance with various embodiments, the at least one desired bending region can be bent in such a way that it has a bending radius of less than approximately 5 mm. Illustratively, edges as sharp as possible, or contours as exact as possible, can be modeled as a result. Illustratively, gaps between the tiles, which arise at the bending regions, can be smaller, the smaller the bending radius.

In accordance with various embodiments, the at least one desired bending region can remain spring-elastically deformable after the bending of the part of the geometric network. Thus, by way of example, an adaptable optoelectronic component can be formed which can be deformed depending on a parameter by virtue of the curvature of the desired bending regions being altered. Illustratively, as a result it is possible to form for example an extendible optoelectronic component (variable or adaptable in its length), e.g. in the form of a pleating. The parameter can be for example a brightness or a time.

To that end, the desired bending regions can be configured in a spring-elastic fashion, e.g. by the encapsulation above the desired bending regions and/or the carrier in the desired bending regions being configured in a spring-elastic fashion. Alternatively or additionally, the desired bending regions of the carrier can be configured in a spring-elastic fashion by the encapsulation being formed before the bending, such that said encapsulation does not subsequently stiffen the bent desired bending regions. Alternatively or additionally, the desired bending regions can be configured in a spring-elastic fashion by the encapsulation above the desired bending regions being severed.

In accordance with various embodiments, an optoelectronic component may include the following: an optically functional layer structure formed in accordance with at least one part of a geometric network of a body, wherein the part of the geometric network includes at least one desired bending region; wherein the part of the geometric network is bent in the at least one desired bending region in such a way that at least one part of the body is formed.

In accordance with various embodiments, a method for producing an optoelectronic component may include the following: forming an optically functional layer structure above an elastic carrier including a plurality of desired bending regions, wherein the optically functional layer structure is formed with a through opening above each of the plurality of desired bending regions; and bending the carrier in the plurality of desired bending regions in such a way that the latter have a bending radius of less than approximately 5 mm.

Illustratively, as a result it is possible to form an adaptable optoelectronic component having edges as sharp as possible, e.g. in the form of a pleating.

In accordance with various embodiments, an optoelectronic component may include the following: a carrier; an optically functional layer structure arranged above the carrier, wherein the carrier includes a plurality of desired bending regions which are free of the optically functional layer structure; wherein the carrier is bent with a bending radius of less than approximately 5 mm in at least the plurality of desired bending regions.

In accordance with various embodiments, a method for producing an optoelectronic component may include the following: forming an optoelectronic component unit above a continuous section of an elastic carrier, wherein the continuous section of the carrier has the shape of at least part of a geometric network of a body which simulates a surface of the body when spread out; and severing the elastic carrier along a path which delimits the section of the carrier.

In accordance with various embodiments, a method for producing an optoelectronic component may include the following: forming a plurality of optoelectronic component units above an elastic carrier having a plurality of desired bending regions which run linearly in each case and which remain free of the plurality of optoelectronic component units or are correspondingly uncovered (e.g. by part of the optically functional layer structure being removed); forming a metallization layer, which electrically connects the plurality of optoelectronic component units to one another and which has exposed contact regions; forming an encapsulation above the plurality of optoelectronic component units and above the plurality of desired bending regions; severing the carrier along a path which at least partly surrounds the plurality of optoelectronic component units, wherein the carrier remains unsevered in the plurality of desired bending regions; and deforming the carrier in the plurality of desired bending regions in such a way that the latter each have a bending radius of less than approximately 5 mm, such that the plurality of optoelectronic component units are arranged at an angle (also referred to as bending angle) with respect to one another.

In accordance with various embodiments, a first optoelectronic component unit can have the shape of a polygon and a second optoelectronic component unit can have the shape of an oval. Alternatively, the first optoelectronic component unit and the second optoelectronic component unit can have the shape of a polygon.

The desired bending regions running linearly are extended linearly in one direction. At least two of the desired bending regions can run non-parallel to one another.

In accordance with various embodiments, the carrier can be applied to a main body in order to deform the latter, wherein the optoelectronic component at least partly covers the surface of the body. The main body can be formed e.g. monolithically.

In accordance with various embodiments, the carrier can be planar during the process of forming the optically functional layer structure. As a result, the optically functional layer structure can be formed for example by means of a direct coating method, which considerably simplifies the requisite processing installation and the method and thereby saves costs.

In accordance with various embodiments, a method for producing an optoelectronic component may include the following: forming a continuous optically functional layer structure in accordance with at least one part of a geometric network of a body, wherein the part of the geometric network includes a plurality of desired bending regions; bending the part of the geometric network, such that at least one part of the body is formed.

In accordance with various embodiments, the section of the carrier may include a desired bending region running linearly. The desired bending region running linearly can adjoin a first optoelectronic component unit and a second optoelectronic component unit, which are adjacent to one another.

In accordance with various embodiments, the second optoelectronic component unit can be formed at a distance from the first optoelectronic component unit, such that they jointly form a gap above the desired bending region. The gap can illustratively have the effect that the carrier is freed of the optically functional layer structure in the desired bending region.

In accordance with various embodiments, severing the carrier can be effected in such a way that the section in the desired bending region remains unsevered.

In accordance with various embodiments, the desired bending region can form an edge of the body when the carrier is deformed, e.g. bent, wherein the edge adjoins two outer surfaces of the body which are formed by the first optoelectronic component unit and the second optoelectronic component unit.

In accordance with various embodiments, the body can be a hollow body (e.g. hollow cylinder) and/or have at least one cavity. The cavity can optionally be open toward the outside. By way of example, the body can have at least one opening and/or at least one depression. Alternatively or additionally, the cavity can be delimited by at least one sidewall (which includes e.g. an outer surface of the body) at at least one side (e.g. on opposite sides). By way of example, the cavity can be enclosed by at least one (i.e. one or more than one) sidewall, e.g. partly or completely. By way of example, the cavity can be completely enclosed by at least one sidewall of the body.

In accordance with various embodiments, the body can have at least one edge (e.g. one, two, three, four, five, six, seven, eight, nine, ten or more than ten edges). Alternatively or additionally, the body can have at least one outer surface (e.g. one, two, three, four, five, six, seven, eight, nine, ten or more than ten outer surfaces) and/or can have at least one sidewall (e.g. one, two, three, four, five, six, seven, eight, nine, ten or more than ten sidewalls).

In accordance with various embodiments, an optoelectronic component may include or be formed from an optically functional layer structure. In accordance with various embodiments, the optoelectronic component can be formed as an organic optoelectronic component, that is to say that the optically functional layer structure may include one or a plurality of organic semiconductors, e.g. in the form of an organic light-emitting diode (OLED). In other words, the optically functional layer structure can be part of an optoelectronic component.

The light generated by the optoelectronic component may include for example ultraviolet (UV) light, visible light and/or infrared (IR) light. Furthermore, the wavelength of the light or the wavelength spectrum of the light can be in the UV range, in the visible range and/or in the IR range.

In accordance with various embodiments, an optoelectronic component can be based on the principle of electroluminescence.

In accordance with various embodiments, the optically functional layer structure may include a plurality of organic and/or inorganic layers which are stacked one above another and form a so-called layer stack. By way of example, it is possible to form more than three, more than four, more than five, more than six, more than seven, more than eight or more than nine layers one above another, e.g. more than ten, e.g., more than twenty, layers.

Alternatively or additionally, the optoelectronic component may include at least one further layer, e.g.

a layer formed as an electrode, a barrier layer and/or an encapsulation layer. Alternatively or additionally, the optoelectronic component may include a plurality of further layers, as mentioned above, e.g. in combination with one another.

Forming a layer (e.g. an organic layer, a layer of the optically functional layer structure and/or a layer of an optoelectronic component) can be effected by means of liquid phase processing, for example. Liquid phase processing may include dissolving or dispersing a substance for the layer (e.g. for an organic layer or an inorganic layer, e.g. a ceramic or metallic layer) in a suitable solvent, for example in a polar solvent such as water, dichlorobenzene, tetrahydrofuran and phenetole, or for example in an apolar solvent such as toluene or other organic solvents, for example in fluorine-based solvent, also called perfluorinated solvent, in order to form a liquid phase of the layer.

Furthermore, forming the layer by means of liquid phase processing may include forming, e.g. applying, the liquid phase of the layer by means of liquid phase deposition (also referred to as a wet-chemical method or wet-chemical coating) on or above a surface to be coated (e.g. on or above the substrate or on or above some other layer of the organic optoelectronic component).

Alternatively or additionally, forming a layer can be carried out by means of vacuum processing (also referred to as a vapor deposition method or vapor phase deposition method). Vacuum processing may include forming a layer (e.g. an organic layer and/or an inorganic layer) by means of one or a plurality of the following methods: atomic layer deposition (ALD), sputtering, thermal evaporation, plasma enhanced atomic layer deposition (PEALD), plasmaless atomic layer deposition (PLALD) or chemical vapor deposition (CVD), e.g. a plasma enhanced chemical vapor deposition (PECVD) method or a plasmaless chemical vapor deposition (PLCVD) method.

In accordance with various embodiments, forming a layer can be effected in combination with a mask (also referred to as a shadow mask or stencil). The mask can have a pattern, for example, which can be imaged onto or over the coated surface, such that the coated surface has the shape of the pattern. By way of example, the pattern can be formed by means of a through opening in the mask, e.g. in a plate. Through the through opening, the material (i.e. as the gas phase or liquid phase thereof) of the layer can pass onto or over the surface to be coated. By way of example, a cutout can be formed in a layer by means of a mask.

Alternatively or additionally, at least some layers can be formed by means of vacuum processing and other layers by means of liquid phase processing, i.e. by means of so-called hybrid processing in which at least one layer (e.g. three or more layers) is processed from a solution (i.e. as liquid phase) and the remaining layers are processed in a vacuum.

Forming a layer can be effected in a processing chamber, for example in a vacuum processing chamber or a liquid phase processing chamber.

One or a plurality of layers, e.g. organic layers of the organic optoelectronic component, can be crosslinked with one another, e.g. after they have been formed. In this case, a multiplicity of individual molecules of the layers can be linked with one another to form a three-dimensional network. This can improve the resistance of the organic optoelectronic component, e.g. vis-à-vis solvents and/or environmental influences.

In the context of this description, an optoelectronic component can be understood to mean a component which emits or absorbs electromagnetic radiation by means of a semiconductor component. The electromagnetic radiation can be for example light in the visible range, UV light and/or infrared light, e.g. light of a color valence (also referred to in that case as emission color).

In accordance with various embodiments, an optoelectronic component can be formed as an electromagnetic radiation-generating and -emitting component, e.g. as an organic light-emitting diode (OLED) or as an organic light-emitting transistor.

In accordance with various embodiments, an organic optoelectronic component can be formed as an electromagnetic radiation-absorbing component, e.g. as a light-absorbing diode or transistor, for example as a photodiode, or as a solar cell.

In accordance with various embodiments, the optoelectronic component can be part of an integrated circuit. Alternatively or additionally, a plurality of electromagnetic radiation-absorbing components and/or component units can be provided, for example in a manner arranged on or above a common carrier (and/or substrate) and/or in a manner accommodated in a common housing. By way of example, a plurality of components and/or component units can be formed from a common optically functional layer structure. A plurality of electromagnetic radiation-emitting components (and/or component units) can for example interact with one another and e.g. generate and emit light being mutually superimposed, with the result that e.g. a color valence such as white can be set or a colored pattern, e.g. an image, can be generated.

In the context of this description, a color of an object or of a light and/or a color valence of a light can be understood to mean a wavelength range of an electromagnetic radiation that is associated with the color or color valence. A color valence can be specified as a color locus in a standard chromaticity diagram.

In accordance with various embodiments, an organic optoelectronic component may include one or a plurality of organic layers. Additionally, the organic optoelectronic component may include one or a plurality of inorganic layers (e.g. in the form of electrodes or barrier layers).

In the context of this description, an organic layer can be understood to mean a layer which includes or is formed from an organic material. Analogously thereto, an inorganic layer can be understood to mean a layer which includes or is formed from an inorganic material. Analogously thereto, a metallic layer can be understood to mean a layer which includes or is formed from a metal. The term “material” can be used synonymously with the term “substance”.

A compound in the sense of a substance (e.g. an organic, inorganic or organometallic compound) can be understood to mean a substance composed of two or more different chemical elements which are chemically bonded together, for example a molecular compound (also referred to as a molecule), an ionic compound, an intermetallic compound or a higher-order compound (also referred to as a complex).

In the context of this description, a metal may include at least one metallic element, e.g. copper (Cu), silver (Ag), platinum (Pt), gold (Au), magnesium (Mg), aluminum (Al), barium (Ba), indium (In), calcium (Ca), samarium (Sm) or lithium (Li). Furthermore, a metal may include a metal compound (e.g. an intermetallic compound or an alloy), e.g. a compound composed of at least two metallic elements, such as e.g. bronze or brass, or e.g. a compound composed of at least one metallic element and at least one nonmetallic element, such as e.g. steel.

In the context of this description, the term “two-dimensional” (also designated as 2D or 2-D) can be understood to mean that a 2D surface is planar, i.e. has no curvature. A 2D body is delimited by two opposite 2D surfaces which, illustratively, are at a small distance from one another. In other words, a 2D body is formed in a plate-shape fashion, e.g. as a film.

In the context of this description, the term “two-and-a-half-dimensional” (also designated as 2½D, 2½D or 2.5D) can be understood to mean that a 2.5D body corresponds to a 2D body that is curved into the third dimension. In other words, on the surface of a 2.5D body a plurality of point pairs can be found which can be connected in each case by a line (connecting line) which lies within the surface, wherein the connecting lines of all the point pairs run parallel to one another. Illustratively, the curvature of the 2.5D body has one and the same direction of curvature at all locations. In other words, a 2.5D body can be represented by a curved 2D body.

In the context of this description, the term “three-dimensional” (also designated as 3D or 3-D) can be understood to mean that a 3D body cannot be represented by a curved 2D body alone. By way of example, a 3D body is delimited by at least one surface which has a plurality of directions of curvature. By way of example, representing a 3D body requires one or a plurality of 2.5D bodies and/or one or a plurality of 2D bodies which are joined together to form the 3D body.

In the context of this description, a network of a body (also designated body network) can be understood as the unfolding of the body that maps the surface thereof onto a two-dimensional plane. The body can be a geometric body. The surface of the body may include at least one planar surface (2D surface) and/or at least one curved surface.

By way of example, the body may include both a planar surface and a curved surface, such as e.g. in the case of a cylinder or a cone. Alternatively, the body can be a geometric body whose surface is composed exclusively of curved surfaces, such as in the case of an ellipsoid (e.g. a sphere). Alternatively, the body can be a geometric body whose surface is composed exclusively of planar surfaces, such as in the case of a polyhedron (e.g. a cube, a tetrahedron, a pyramid, a prism or an octahedron). Alternatively or additionally, the body may include through openings, depressions and/or projections.

Alternatively or additionally, the body may include two surface sections which adjoin one another at an angle with respect to one another and form an edge of the body. The surface sections can be in each case part of one or two outer surfaces (e.g. side surfaces) of the body which run at an angle with respect to one another. A body can have an edge for example even if it includes exclusively a continuous surface, such as in the case of an oloid, for example, wherein the surface sections in this case are part of the continuous outer surface. Alternatively or additionally, the body may include three surface sections which run at an angle with respect to one another and form a corner of the body at the location at which they adjoin one another.

Illustratively, the body network can also be understood as an envelope of the body, which when spread out represents the surfaces of the body in the form of a diagram in the plane after the body has been cut open at some edges.

A body network can be folded together to form the body by being bent in the desired bending regions. The 3D shape of a body to which the body network is assigned can be reconstructed as a result. A body network may include a plurality of body network segments, for example, wherein two body network segments in each case adjoin a common desired bending region. A body network segment can form for example a planar outer surface of the body. Alternatively, a body network segment can form for example a curved outer surface of the body, such as e.g. the lateral surface of a cylinder. In that case, the body network segment can be curved in order to form the body from the body network.

A body network can be assigned to exactly one body. By contrast, a body can be assigned more than one body network, e.g. more than two, more than three, etc. Illustratively, there can be more than one possible unfolding for a body. The body networks assigned to a body can differ in the arrangement of the body network segments. A body in the form of a cube can be assigned for example exactly eleven body networks having the same number of body network segments, namely exactly 6 (cf. FIG. 6A and FIG. 6B). Alternatively, the body networks assigned to a body can differ in the number of body network segments, as in the case of a sphere (cf. FIG. 9A and FIG. 9B).

The optoelectronic component formed in accordance with various embodiments can be self-supporting, i.e. require no further stiffening carrier. By way of example, the body network can be configured in a self-supporting fashion.

### BRIEF DESCRIPTION OF THE DRAWINGS

In the drawings, like reference characters generally refer to the same parts throughout the different views.

The drawings are not necessarily to scale, emphasis instead generally being placed upon illustrating the principles of the disclosed embodiments. In the following description, various embodiments described with reference to the following drawings, in which:

FIG. 1 shows a schematic flow diagram of a method in accordance with various embodiments for producing an optoelectronic component;

FIG. 2A shows a schematic plan view or side view of an optoelectronic component in accordance with various embodiments in a method in accordance with various embodiments for producing an optoelectronic component;

FIG. 2B shows a schematic perspective view of an optoelectronic component in accordance with various embodiments in a method in accordance with various embodiments for producing an optoelectronic component;

FIG. 3A shows a schematic plan view or side view of an optoelectronic component in accordance with various embodiments in a method in accordance with various embodiments for producing an optoelectronic component;

FIG. 3B shows a schematic perspective view of an optoelectronic component in accordance with various embodiments in a method in accordance with various embodiments for producing an optoelectronic component;

FIG. 4 shows a schematic flow diagram of a method in accordance with various embodiments for producing an optoelectronic component;

FIG. 5A and FIG. 5B show in each case a schematic cross-sectional view or side view of an optoelectronic component in accordance with various embodiments in a method in accordance with various embodiments for producing an optoelectronic component;

FIG. 6A shows a schematic plan view or side view of an optoelectronic component in accordance with various embodiments in a method in accordance with various embodiments for producing an optoelectronic component;

FIG. 6B shows a schematic perspective view of an optoelectronic component in accordance with various embodiments in a method in accordance with various embodiments for producing an optoelectronic component;

FIG. 7 shows a schematic plan view or side view of an optoelectronic component in accordance with various embodiments in a method in accordance with various embodiments for producing an optoelectronic component;

FIG. 8A shows a schematic plan view or side view of an optoelectronic component in accordance with various embodiments;

FIG. 8B shows a schematic cross-sectional view or side view of the optoelectronic component in accordance with various embodiments as illustrated in FIG. 8A;

FIG. 9A and FIG. 9B show in each case a schematic plan view or side view of an optoelectronic component in accordance with various embodiments in a method in accordance with various embodiments for producing an optoelectronic component;

FIG. 10 shows a schematic perspective view of an optoelectronic component in accordance with various embodiments;

FIG. 11A and FIG. 11B show in each case a schematic perspective view of an optoelectronic component in accordance with various embodiments;

FIG. 12A and FIG. 12B show in each case a schematic perspective view of an optoelectronic component in accordance with various embodiments;

FIG. 13 shows a schematic perspective view of an optoelectronic component in accordance with various embodiments;

FIG. 14A to FIG. 14C show in each case a schematic cross-sectional view or side view of an optoelectronic component in accordance with various embodiments in a method in accordance with various embodiments for producing an optoelectronic component;

FIG. 15A shows a schematic cross-sectional view or side view of an optoelectronic component in accordance with various embodiments in a method in accordance with various embodiments for producing an optoelectronic component;

FIG. 15B shows a schematic cross-sectional view or plan view of an optoelectronic component in accordance with various embodiments in a method in accordance with various embodiments for producing an optoelectronic component;

FIG. 15C and FIG. 15D show in each case a schematic cross-sectional view or side view of an optoelectronic component in accordance with various embodiments in a method in accordance with various embodiments for producing an optoelectronic component; and

FIG. 16 shows a schematic perspective view of an optoelectronic component in accordance with various embodiments in a method in accordance with various embodiments for producing an optoelectronic component.

### DETAILED DESCRIPTION

In the following detailed description, reference is made to the accompanying drawings, which form part of this description and show for illustration purposes specific embodiments in which the present disclosure can be implemented. In this regard, direction terminology such as, for instance, “at the top”, “at the bottom”, “at the front”, “at the back”, “front”, “rear”, etc. is used with respect to the orientation of the figure(s) described. Since component parts of embodiments can be positioned in a number of different orientations, the direction terminology serves for illustration and is not restrictive in any way whatsoever. It goes without saying that other embodiments can be used and structural or logical changes can be made, without departing from the scope of protection of the present disclosure. It goes without saying that the features of the various exemplary embodiments described herein can be combined with one another, unless specifically indicated otherwise. Therefore, the following detailed description should not be interpreted in a restrictive sense, and the scope of protection of the present disclosure is defined by the appended claims.

In the context of this description, the terms “connected” and “coupled” are used to describe both a direct and an indirect connection and a direct or indirect coupling. In the figures, identical or similar elements are provided with identical reference signs, in so far as this is expedient.

Furthermore, in the context of this description, the formulation “above” in association with forming a layer can be understood to mean that a layer formed above a surface (e.g. of a carrier) or a component part (e.g. a carrier) is formed in direct physical contact with the surface or the component part. Furthermore, the formulation “above” can be understood to mean that one or a plurality of further layers are arranged between the layer and the component part.

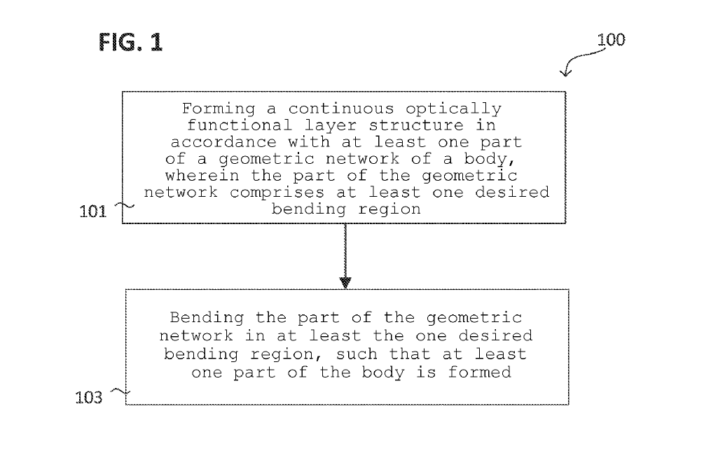

FIG. 1 illustrates a schematic flow diagram of a method 100 in accordance with various embodiments for producing an optoelectronic component.

The method 100 includes, in 101, forming an optically functional layer structure in accordance with at least one part of a body network. The part of the body network may include at least one desired bending region. Alternatively or additionally, the part of the body network may include a plurality of desired bending regions. The desired bending regions can for example be arranged between two 2D surfaces of the body network (also referred to as body network segments) (and illustratively later form an edge of the body), or be extended along a surface to be curved of the body network (and illustratively later form a curved outer surface of the body).

Furthermore, the method 100 includes, in 103, bending the part of the geometric network, such that at least one part of the body is formed. The part of the body network can be bent in at least the one desired bending region. Alternatively or additionally, the part of the body network can be bent in at least the plurality of desired bending regions. The body formed from the body network can also be referred to as body image. Illustratively, the geometric network can be folded together to form an image of the body.

Bending the part of the geometric network may include folding the part of the geometric network. In other words, e.g. an OLED display substrate can be folded.

Folding can be understood to mean that the body network is bent at the locations at which the optically functional layer structure is cut out, i.e. between the body network segments to which individual luminous surfaces of the optoelectronic component can respectively be assigned. Alternatively or additionally, the body network can be bent in a luminous surface of the optoelectronic component only to an extent such that the optically functional layer structure remains undamaged.

By repeatedly performing the method steps described above, it is possible to create e.g. complex 3D OLED display structures.

The part of the body network can be e.g. an incomplete body network or a complete body network. By way of example, the part of the body network can be formed from the body network by a cutout being formed in the body network. The cutout can form for example a through opening in the body network. The cutout can serve to establish a connection between the interior and the exterior of the body image formed later from the body network. In other words, the body network can have an opening. Through the opening, for example, an electrical line can be led into the interior of the body image.

Alternatively or additionally, the part of the body network can be formed by an outer surface of the body network being removed. By way of example, the absent outer surface of the body network can later be a surface on which the body image stands, i.e. a surface which need not necessarily emit light.

In accordance with various embodiments, the part of the body network can correspond to the body network to the extent of more than approximately 50% (illustratively cover the body to the extent of more than approximately 50%), e.g. to the extent of more than approximately 60%, e.g. to the extent of more than approximately 70%, e.g. to the extent of more than approximately 80%, e.g. to the extent of more than approximately 90%, e.g. to the extent of more than approximately 99%.

The method 100 makes it possible for example to produce a planar, flexible optoelectronic component (e.g. an OLED display) by means of vacuum processing (can also be referred to as a vapor deposition process), which optoelectronic component illustratively is converted into a 3D shape afterward by cutting out and folding.

Illustratively, for the production of an optoelectronic 3D component (e.g. a 3D OLED display), firstly a 2D basis is chosen. The latter can be a flexible substrate, for example, on which individual luminous surfaces, but also non-luminous or transparent regions, are arranged. The optically functional layer structure can be applied, e.g. vapor-deposited, onto the substrate. In addition, it may be necessary to sever (e.g. cut into) the substrate. This may be necessary if the substrate (also referred to as carrier) has a shape different than the body network. The optically functional layer structure can then be applied to the substrate in accordance with at least one part of the body network and then be separated from the substrate along a path surrounding the part of the body network.

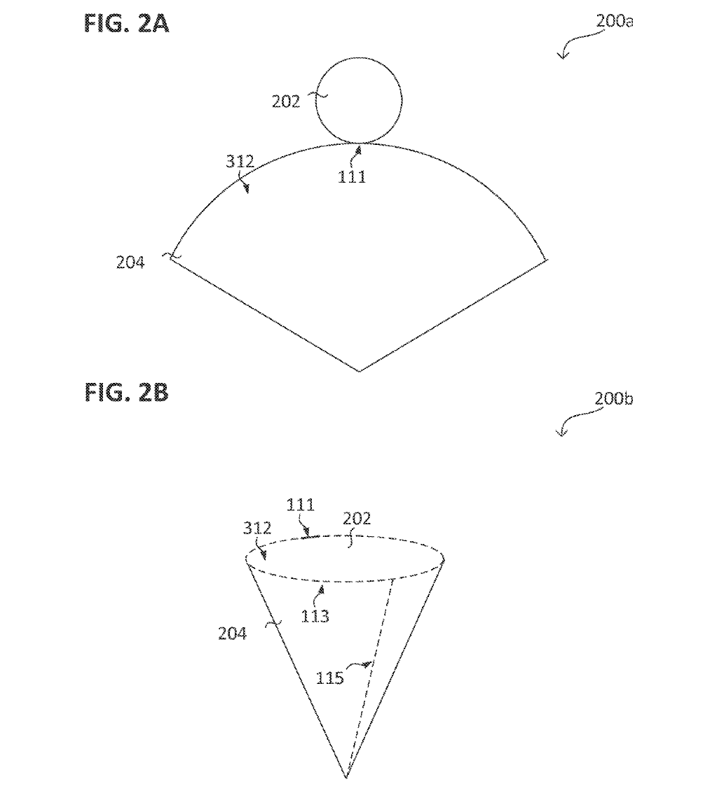

FIG. 2A illustrates a schematic plan view or side view of an optoelectronic component 200a in accordance with various embodiments in a method in accordance with various embodiments for producing an optoelectronic component.

The optoelectronic component 200a may include an optically functional layer structure 312 formed in accordance with the body network of a cone.

The optoelectronic component 200a may include a first segment 202 of the body network (can also be referred to as a first body network segment 202) and a second segment 204 of the body network (can also be referred to as a second body network segment 204). The first body network segment 202 and the second body network segment 204 can together form the body network of the optoelectronic component 200a.

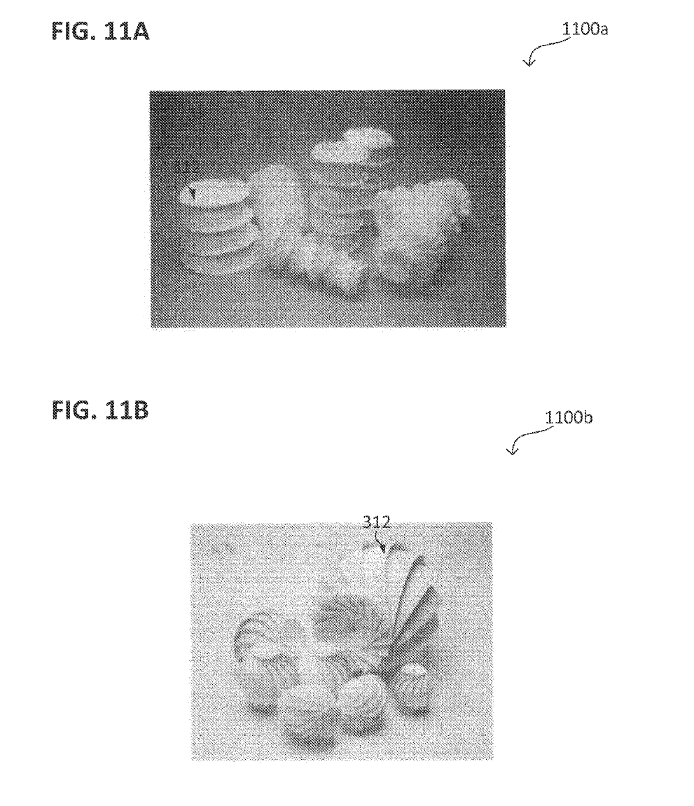

At the location at which the first body network segment 202 and the second body network segment 204 adjoin one another, it is possible to form a desired bending region 111, as described below (cf. FIG. 11).

FIG. 2B illustrates a schematic perspective view of an optoelectronic component 200b in accordance with various embodiments in a method in accordance with various embodiments for producing an optoelectronic component. The optoelectronic component 200b shown in FIG. 2B substantially corresponds to the optoelectronic component 200a shown in FIG. 2A, which is bent in at least the desired bending region 111.

The body network of the optoelectronic component 200a which is bent, as illustrated in FIG. 2B, can form an optoelectronic component 200a in the form of a cone. The first body network segment 202 can form the base surface of the cone and the second body network segment 204 can form the side surface of the cone, said side surface being curved.

In this case, marginal regions of the body network which do not have a shared desired bending region 111 can be joined together in such a way that they adjoin one another and form joining regions (illustrated in a dashed manner) in the form of an edge 113 or in the form of a joint 115. At the joining regions, it is possible to connect, e.g. adhesively bond, the first body network segment 202 and the second body network segment 204 to one another, or the second body network segment 204 to itself, such that the shape of the optoelectronic component 200b can be stabilized.

The optoelectronic component 200b can alternatively also be formed from other body networks, differently than the optoelectronic component 200a illustrated in FIG. 2A.

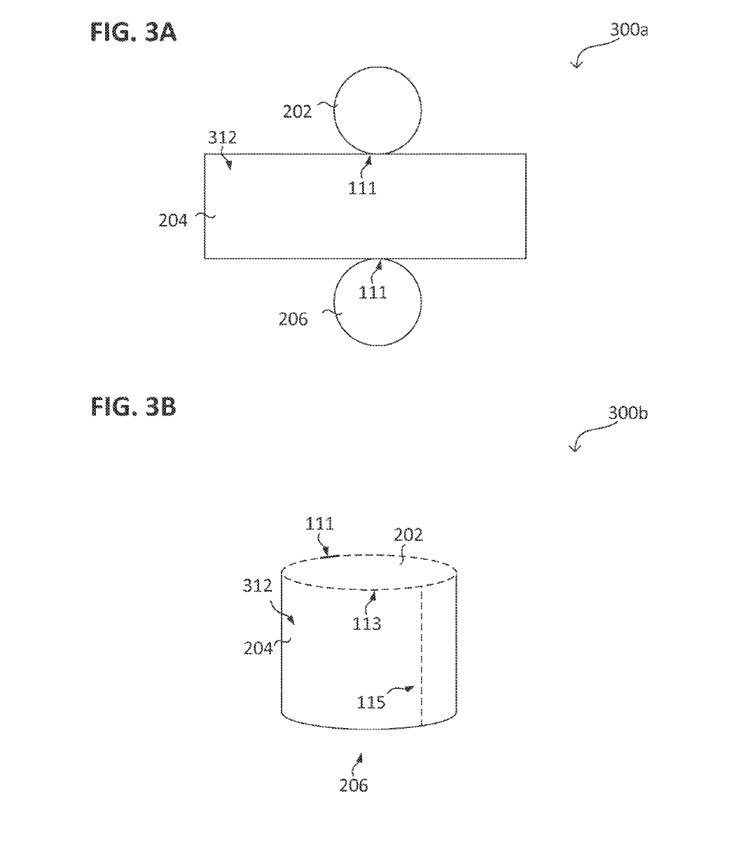

FIG. 3A illustrates a schematic plan view or side view of an optoelectronic component 300a in accordance with various embodiments in a method in accordance with various embodiments for producing an optoelectronic component.

The optoelectronic component 300a may include a first body network segment 202, a second body network segment 204 and a third body network segment 206. The first body network segment 202, the second body network segment 204 and the third body network segment 206 can together form the body network of the optoelectronic component 300a.

At the location at which the first body network segment 202 and the second body network segment 204 adjoin one another, and at the location at which the second body network segment 204 and the third body network segment 206 adjoin one another, it is possible to form in each case a desired bending region 111, as described below (cf. FIG. 11).

FIG. 3B illustrates a schematic perspective view of an optoelectronic component 300b in accordance with various embodiments in a method in accordance with various embodiments for producing an optoelectronic component. The optoelectronic component 300b shown in FIG. 3B substantially corresponds to the optoelectronic component 300a shown in FIG. 3A which is bent in at least the desired bending regions 111.

The body network of the optoelectronic component 300a which is bent, as illustrated in FIG. 3B, can form an optoelectronic component 300a in the form of a cylinder. The first body network segment 202 can form the top surface of the cylinder, the second body network segment 204 can form the side surface (which is curved) of the cylinder, and the third body network segment 204 (hidden in the view) can form the base surface of the cylinder.

Analogously to the text described above, it is possible to form joining regions (illustrated in a dashed manner) in the form of an edge 113 or in the form of a joint 115, at which the body network segments 202, 204 and 206 can be connected to one another.

The optoelectronic component 300b can alternatively also be formed from other body networks, differently than the optoelectronic component 300a illustrated in FIG. 3A.

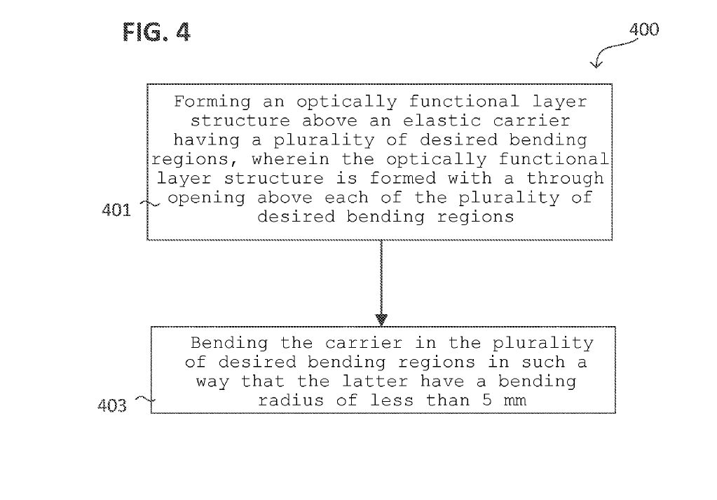

FIG. 4 illustrates a schematic flow diagram of a method 400 in accordance with various embodiments for producing an optoelectronic component.

The method 400 may include, in 401, forming an optically functional layer structure above an elastic carrier including a plurality of desired bending regions. The optically functional layer structure can be formed with a cutout above each of the plurality of desired bending regions, e.g. in such a way that the cutout penetrates through the optically functional layer structure (in other words in the form of a through opening).

The cutout can be formed by, for example, the carrier not being coated in the desired bending regions or the optically functional layer structure being removed above the desired bending regions. In other words, the carrier can be freed of the optically functional layer structure in the desired bending regions.

Furthermore, the method 400 may include, in 403, bending the carrier in the plurality of desired bending regions in such a way that the latter have a bending radius of less than approximately 5 mm, as described below.

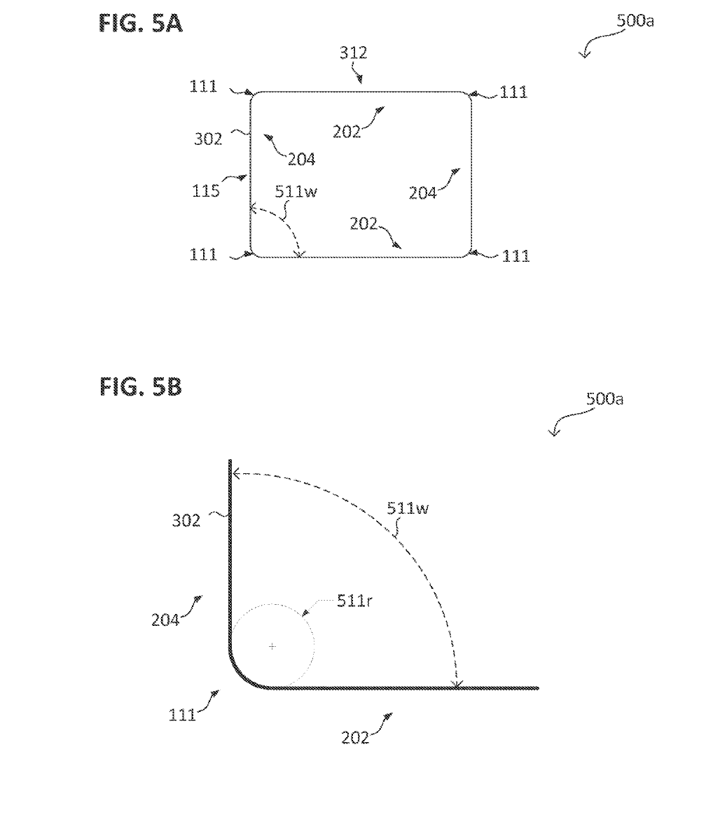

FIG. 5A and FIG. 5B illustrate in each case a schematic cross-sectional view or side view of an optoelectronic component 500a in accordance with various embodiments in a method in accordance with various embodiments for producing an optoelectronic component.

The optoelectronic component 500a may include a carrier 302. On the carrier 302, the optically functional layer structure (not illustrated) is formed in accordance with a body network, e.g. by means of vacuum processing.

Furthermore, the carrier 302 may include a plurality of desired bending regions 111, in which the carrier 302 is bent. Between two adjacent desired bending regions 111, in each case a planar section of the carrier 302 can be extended, in which the carrier 302 is e.g. scarcely or not bent.

With more than one desired bending region 111, it is possible to achieve for example a self-contained shape of the carrier 302, e.g. with two, three or four desired bending regions 111 as illustrated in FIG. 5B. Alternatively or additionally, the carrier 302 may include more than four desired bending regions 111, e.g. more than five, more than six, more than seven, more than eight or more than nine desired bending regions 111, e.g. more than ten, e.g. more than twenty, desired bending regions 111.

FIG. 5B illustrates a detailed view of a desired bending region 111. The bent desired bending region 111 can be defined by a bending angle 511w and a bending radius 511r.

The bending radius 511r denotes the radius of a circle that nestles against the contour of the desired bending region 111. By way of example, the desired bending region 111 can be bent onto or around a rod having a radius equal to that of the bending radius 511r. In other words, the desired bending region 111 has a curvature corresponding to the curvature of a circle having a radius equal to the bending radius 511r. If the contour of the desired bending region 111 is not bent uniformly, i.e. if the desired bending region 111 is curved non-uniformly, the bending radius 511r of the desired bending region 111 can correspond to the radius of a circle having a curvature corresponding to the greatest curvature of the desired bending region 111.

The carrier 302 can be bent in the desired bending region 111 with a bending radius 511r of less than approximately 5 mm, e.g. have a bending radius of less than approximately 4.5 mm, e.g. of less than approximately 4 mm, e.g. of less than approximately 3.5 mm, e.g. of less than approximately 3 mm, e.g. of less than approximately 2.5 mm, e.g. of less than approximately 2 mm, e.g. of less than approximately 1.5 mm, e.g. of less than approximately 1 mm, e.g. of less than approximately 0.5 mm, e.g. of less than approximately 0.2 mm, e.g. of less than approximately 0.1 mm.

The bending angle 511w of the desired bending region 111 denotes the angle formed by the planar sections of the carrier 302 which adjoin the desired bending region 111, e.g. body network segments 202, 204.

The bending angle 511w can have a value suitable for forming a part of the body. By way of example, the bending angle 511w can have a value in a range of approximately 0° to approximately 180°, e.g. in a range of approximately 20° to approximately 160°, e.g. in a range of approximately 30° to approximately 150°, e.g. in a range of approximately 40° to approximately 140°, e.g. in a range of approximately 50° to approximately 130°, e.g. in a range of approximately 60° to approximately 120°. If e.g. a cube is intended to be formed, the bending angle 511w can have a value of approximately 90°. If e.g. a tetrahedron is intended to be formed, the bending angle 511w can have a value of approximately 70.5°. If e.g. a dodecahedron is intended to be formed, the bending angle 511w can have a value of approximately 116.6°.

The optically functional layer structure (not illustrated) can be arranged on each of the two sides of the carrier 302, e.g. on one of the two sides or on both sides.

If the desired bending region 111 is freed of the optically functional layer structure, the minimum bending radius 511r is no longer limited by the loading capacity of the optically functional layer structure, but rather is defined by the loading capacity of the carrier 302. A material of the carrier 302 can be chosen in such a way that illustratively the smallest possible bending radius 511r is attained. By way of example, a desired bending region 111 can be bent with a bending radius 511r in a range of approximately 0.1 mm to approximately 3 mm.

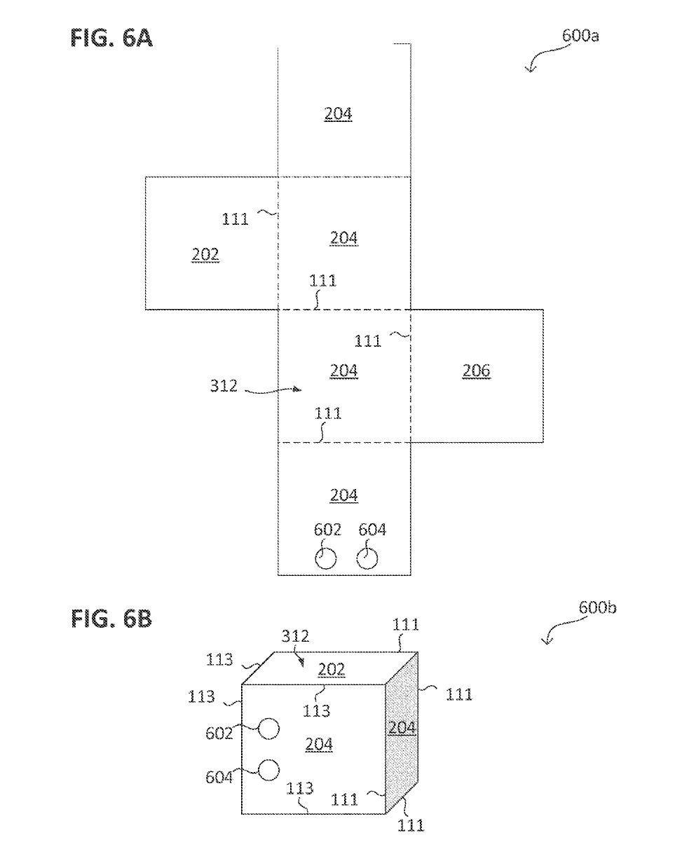

FIG. 6A illustrates a schematic plan view or side view of an optoelectronic component 600a in accordance with various embodiments in a method in accordance with various embodiments for producing an optoelectronic component.

The optoelectronic component 600a may include an optically functional layer structure 312 formed in accordance with the body network of a cube. The body network of the cube may include a plurality of desired bending regions 111 (illustrated in a dashed manner) which run in each case between two adjacent body network segments 202, 204, 206.

The desired bending regions 111 can run in each case linearly and in pairs either parallel to one another or perpendicular to one another. In the case of an arbitrary polyhedron, the desired bending regions 111 can run at a different angle with respect to one another.

Furthermore, the optoelectronic component 600a may include a first contact region 602, e.g. in the form of an exposed first contact pad, and a second contact region 604, e.g. in the form of an exposed second contact pad. The contact pads can be configured for contacting the optoelectronic component 600a, e.g. for bonding, for soldering or the like.

In accordance with various embodiments, forming the optically functional layer structure 312 may include providing contact regions 602, 604, luminous surfaces, transparent regions, conductor tracks, desired bending regions 111 (also referred to as bend locations), openings (e.g. through opening 1000o) and colored regions.

FIG. 6B illustrates a schematic perspective view of an optoelectronic component 600b in accordance with various embodiments in a method in accordance with various embodiments for producing an optoelectronic component. The optoelectronic component 600b illustrated in FIG. 6B can be formed for example from the optoelectronic component 600a illustrated in FIG. 6A, e.g. by the desired bending regions 111 of the optoelectronic component 600a illustrated in FIG. 6A being bent at a bending angle 511w of approximately 90°.

In this case, marginal regions of the body network which do not have shared desired bending regions 111 (i.e. which do not jointly adjoin one of the desired bending regions 111) can be joined together in such a way that they adjoin one another and form joining regions (illustrated in a dashed manner) in the form of an edge 113 of the cube.

At the locations of the body network at which two bending regions 111 meet one another, i.e. at the locations of the body network which, when folded together, form a corner of the cube, an excessively large bending radius 511r prevents the body network segments 204, 204, 206 (also referred to as tiles) adjoining that from being able to be joined together in a flush manner. Therefore, at these locations gaps can occur in the body formed, which gaps become larger as the bending radius increases.

The smaller the bending radius 511r, the smaller can be the gaps between the tiles which form a corner of the cube.

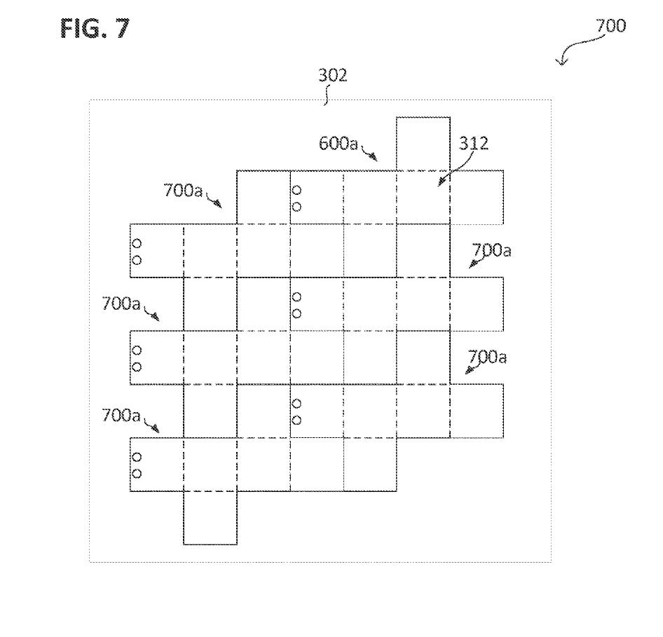

FIG. 7 illustrates a schematic plan view or side view of an optoelectronic component 600a in accordance with various embodiments in a method 700 in accordance with various embodiments for producing one or a plurality of optoelectronic components 600a, 700a.

In accordance with various embodiments, the optically functional layer structure 312 of the optoelectronic component 600a illustrated in FIG. 6A can be formed in accordance with the body network of a cube on a carrier 302, as illustrated in FIG. 7. By way of example, the optically functional layer structure 312 can be formed by regions of the carrier 302 alongside the body network not being coated (e.g. by means of a mask). Alternatively, the optically functional layer structure 312 can be removed from regions of the carrier 302 alongside the body network, e.g. by means of etching.

Analogously thereto, further optoelectronic components 700a can be formed by the optically functional layer structures 312 thereof being formed on the carrier 302, e.g. substantially identically to the optically functional layer structure 312. The optically functional layer structures 312 can be arranged on the carrier 302 in such a way that they intermesh. In this regard, by way of example, a particularly high degree of utilization (also referred to as filling factor) of the carrier 302 can be achieved.

Alternatively or additionally, optically functional layer structures 312 in accordance with different body networks can be formed on a common carrier 302, i.e. can be combined with one another, in order to increase the degree of utilization.

Alternatively or additionally, the arrangement of body networks illustrated in FIG. 7 can be extended by further body networks.

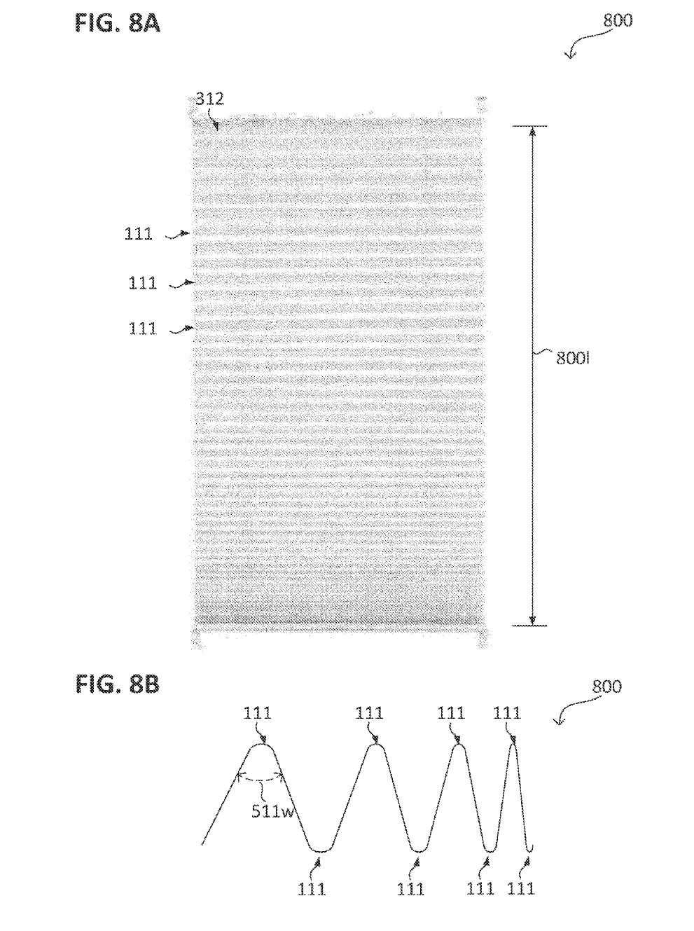

FIG. 8A illustrates a schematic plan view or side view of an optoelectronic component 800 in accordance with various embodiments and FIG. 8B illustrates a schematic cross-sectional view or side view of an optoelectronic component 800 in accordance with various embodiments.

The optoelectronic component 800 includes a plurality of desired bending regions 111, which adjacently in pairs in each case are bent in different directions and have in pairs a mutually different bending radius 511r and in pairs a mutually different bending angle 511w. The desired bending regions 111 run parallel to one another.

An optically functional layer structure (not illustrated) can be formed on the top side of the optoelectronic component 800. Alternatively or additionally, an optically functional layer structure (not illustrated) can be formed on the underside of the optoelectronic component 800.

The optoelectronic component 800 can be formed in the form of a pleating. By way of example, the desired bending regions 111 can still be bendable, e.g. elastically bendable, after the optoelectronic component 800 has been formed. Consequently, the length 8001 of the optoelectronic component 800 can be variable over time, and be varied.

In other words, by folding the carrier 302 in the desired bending regions 111, it is possible to form a pleating which can be formed as a 3D body that is variable over time (also designated as 3.5D).

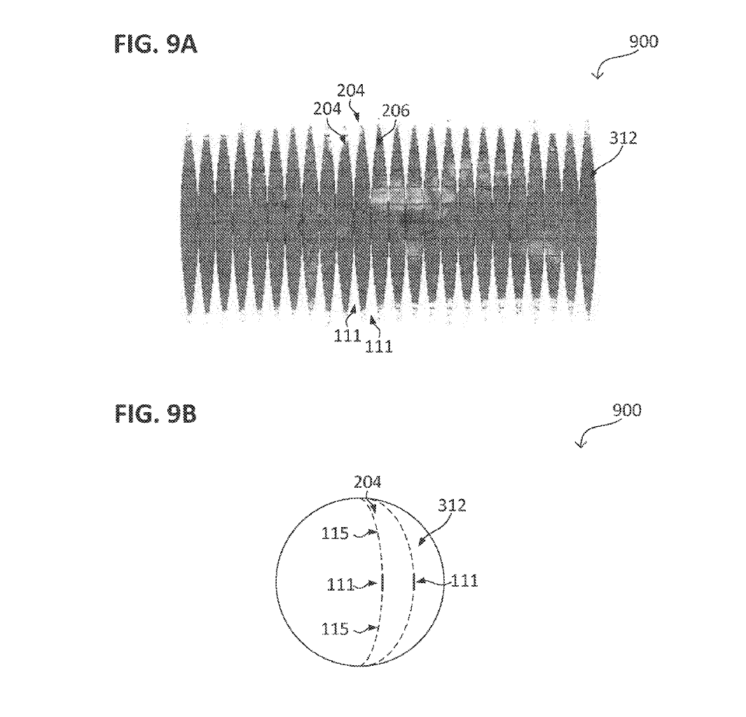

FIG. 9A and FIG. 9B illustrate in each case a schematic plan view or side view of an optoelectronic component 900 in accordance with various embodiments in a method in accordance with various embodiments for producing an optoelectronic component.

In accordance with various embodiments, very complex 3D bodies, such as e.g. a sphere, can be realized by folding and cutting (i.e. severing of the carrier 302).

The optoelectronic component 900 may include an optically functional layer structure 312 formed in accordance with the body network of a sphere. The body network of the sphere may include a plurality of desired bending regions 111 running in each case between two adjacent body network segments 202, 204, 206.

The desired bending regions 111 can in each case run linearly and in pairs parallel to one another.

As is illustrated in FIG. 9B, the optoelectronic component 900 can be formed by the bending of the desired bending regions 111 of the body network illustrated in FIG. 9A.

In this case, marginal regions of the body network which do not have shared desired bending regions 111 can be joined together in such a way that they adjoin one another and form joining regions (illustrated in a dashed manner) in the form of a joint 115. Only the body network segment 204 arranged between the two body network segments 202 and 206 is illustrated in FIG. 9B, for the sake of clarity.

In the case of the sphere, the body networks assigned to the sphere can differ in the number of body network segments 202, 204, 206. The more body network segments 202, 204, 206 the body network of the sphere has, the more precisely the sphere can be simulated.

Illustratively, what can be achieved by means of the small radius of curvature of the desired bending regions 111 is that the gaps between the body network segments 202, 204, 206, which can remain in the joining regions during the joining-together process, turn out to be very small.

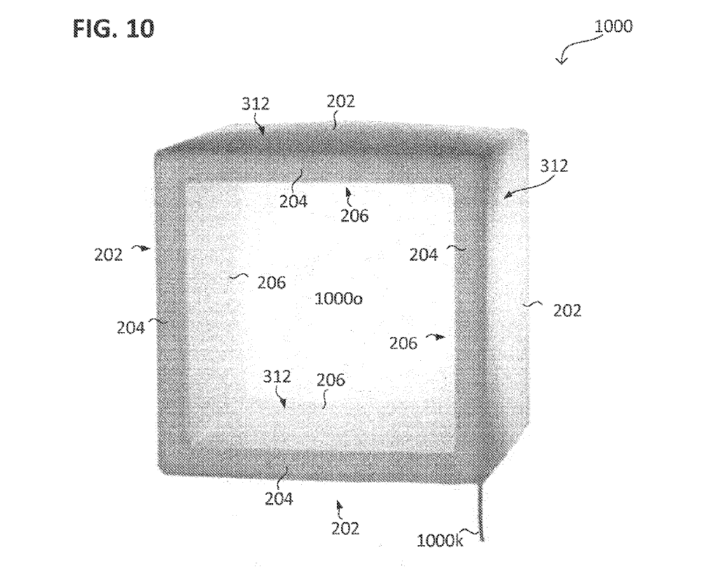

FIG. 10 illustrates a schematic perspective view of an optoelectronic component 1000 in accordance with various embodiments. The optoelectronic component 1000 may include a plurality of first body network segments 202, a plurality of second body network segments 204 and a plurality of third body network segments 206, which respectively adjoin one another in pairs.

The second body network segments 204 adjoining one another can delimit the optoelectronic component 1000 in a lateral direction and the first body network segments 202 adjoining one another can delimit the optoelectronic component 1000 in a direction transverse with respect to the lateral direction. Furthermore, the optoelectronic component 1000 may include a through opening 1000o, which can be delimited by the third body network segments 206 adjoining one another, transversely with respect to the lateral direction.

Each body network segment 202, 204, 206 of the first body network segments 202, of the second body network segments 204 and of the third body network segments 206 can be assigned a luminous surface of the optoelectronic component 1000. In other words, each body network segment 202, 204, 206 can be configured for emitting light (i.e. include or form a luminous surface).

Furthermore, the optoelectronic component 1000 may include an electrical line 1000k, e.g. an electrical cable, which can be electrically conductively connected to the contact regions (hidden in the view) of the optoelectronic component 1000, such that the optoelectronic component 1000 can be supplied with electrical energy by means of the contact regions and the electrical line. The electrical energy can be provided by means of an energy source (also referred to as voltage source or current source), e.g. by means of a driver circuit or a power supply unit. Furthermore, the optoelectronic component 1000 may include a controller, which can be configured for controlling the luminous regions of the optoelectronic component 1000, e.g. all luminous regions together or separately from one another. The controller can control or regulate an electrical voltage, for example, which is fed to the luminous regions from the energy source.

FIG. 11A and FIG. 11B illustrate in each case a schematic perspective view of an optoelectronic component 1100a, 1100b in accordance with various embodiments.

In accordance with various embodiments, complex 3D bodies can be realized by folding and cutting and be provided with luminous surfaces e.g. by means of OLED displays.

In accordance with various embodiments, the optoelectronic components 1100a, 1100b can be formed with a similar shape, and vary in the size thereof, e.g. in the length thereof, as is illustrated in FIG. 11A, or the diameter thereof, as is illustrated in FIG. 11B.

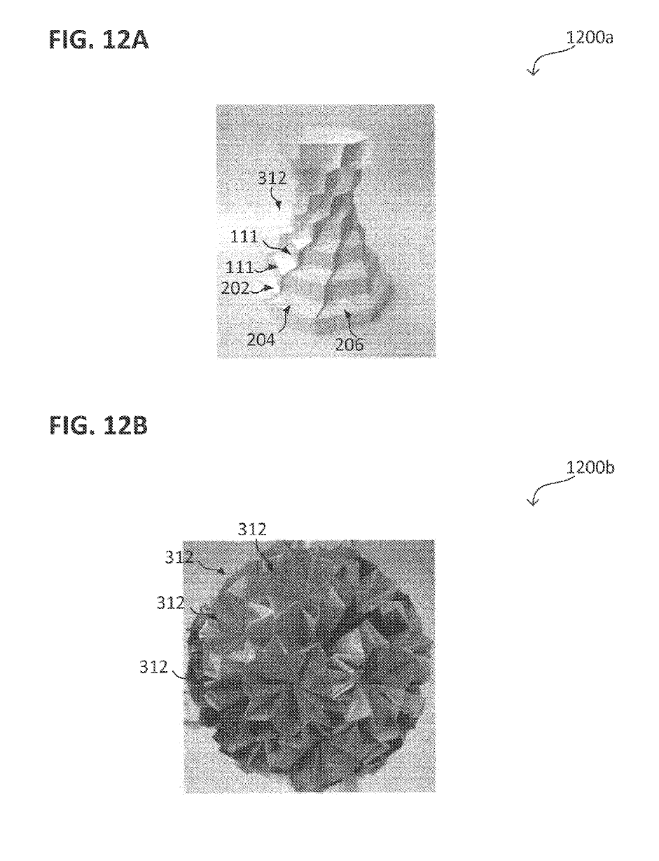

FIG. 12A and FIG. 12B illustrate in each case a schematic perspective view of an optoelectronic component 1200a, 1200b in accordance with various embodiments.

As is illustrated in FIG. 12A, the body can also be composed of a plurality of geometric bodies. Illustratively, the body can have an arbitrary shape, e.g. the shape of an everyday object or article of practical use, such as e.g. furnishings (e.g. a chair or a table).

Analogously to the optoelectronic component 800 illustrated in FIG. 8A, the desired bending regions 111 of the optoelectronic component 1200a adjacently in pairs in each case are bent in different directions. Furthermore, the body network segments 202, 204, 206 are interleaved in one another.

As is illustrated in FIG. 12B, it is possible to realize bodies whose number of outer surfaces is greater than 10, e.g. greater than 20, e.g. greater than 30, e.g. greater than 40, e.g. greater than 50, e.g. greater than 60, e.g. greater than 70, e.g. greater than 80, e.g. greater than 90, e.g. greater than 100.

Analogously, it is possible to realize bodies whose body networks have a number of desired bending regions 111 greater than 10, e.g. greater than 20, e.g. greater than 30, e.g. greater than 40, e.g. greater than 50, e.g. greater than 60, e.g. greater than 70, e.g. greater than 80, e.g. greater than 90, e.g. greater than 100.

Such bodies can be realized by virtue of a plurality of optically functional layer structures 312, which are formed in each case in accordance with a body network, being interleaved in one another. In other words, the optoelectronic component 1200b may include a plurality of optically functional layer structures 312 as described above.

By way of example, a part of the body network which is cut out can serve for connecting a plurality of optically functional layer structures 312 to one another.

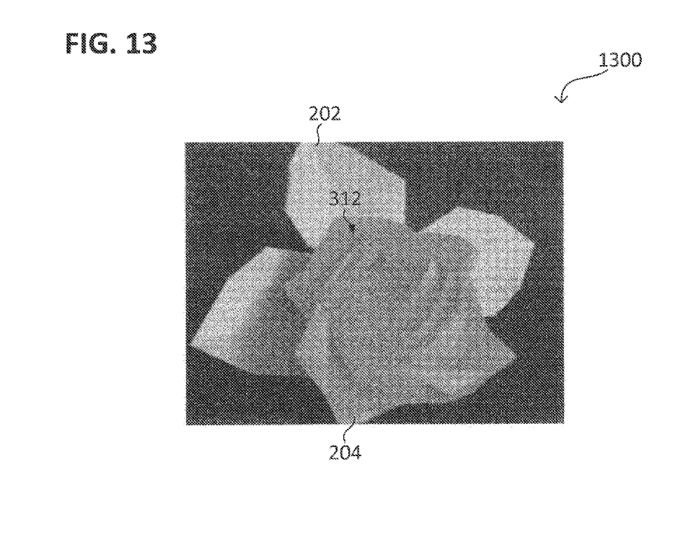

FIG. 13 illustrates a schematic perspective view of an optoelectronic component 1300 in accordance with various embodiments.

In accordance with various embodiments, a first body network segment 202 can emit first light having a first color valance and a first intensity (or first luminance) and a second body network segment 204 can emit second light having a second color valance and a second intensity (or second luminance). The first light can be e.g. different than the second light, e.g. in terms of the intensity and/or in terms of the intensity (or luminance). Illustratively, different-colored luminous surfaces can thus be realized.

In accordance with various embodiments, the first color valance, the second color valance, the first intensity and the second intensity (or luminance) can be controlled or regulated by means of a controller, e.g. jointly or independently of one another (i.e. individually), e.g. in a time-dependent manner or depending on a predefinition which is fed to the controller e.g. by an input device, i.e. e.g. from a user input.

If the optoelectronic component 1200b includes a plurality of optically functional layer structures 312, as described above, a first functional layer structure 312 can be configured for emitting first light and a second functional layer structure 312 can be configured for emitting first light.

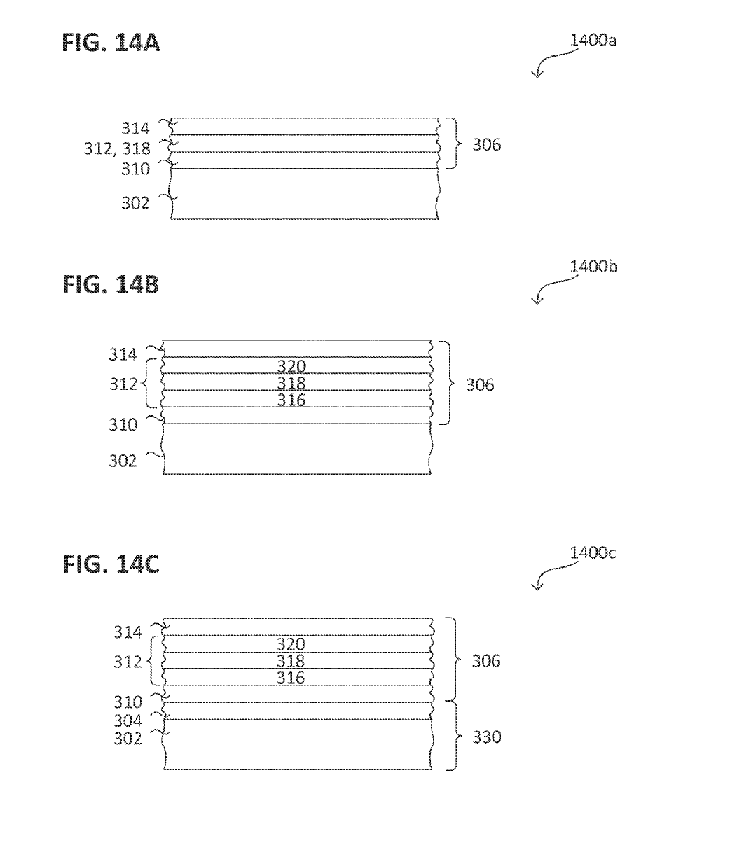

FIG. 14A to FIG. 14C illustrates in each case a schematic cross-sectional view or side view of an optoelectronic component 1400a, 1400b, 1400c in accordance with various embodiments in a method in accordance with various embodiments for producing an optoelectronic component.

The features of the optoelectronic components 1400a, 1400b, 1400c illustrated in FIG. 14A to FIG. 14C can be understood as an alternative or in addition to the features of the optoelectronic components as described above herein, and can be for example part of a lighting device.

FIG. 14A illustrates a sectional illustration or side view of an optoelectronic component 1400a in accordance with various embodiments.

Forming the optoelectronic component 1400a includes forming a first electrode 310, forming a functional layer structure 312 and forming a second electrode 314, which together are part of the optoelectronic component 1400a and are arranged on or above a substrate 302 (also referred to as a carrier 302).

The functional layer structure 312 can be formed as an organic functional layer structure 312.

In accordance with various embodiments, the first electrode 310, the functional layer structure 312 and the second electrode 314 form an organic light-emitting diode 306 as described below and as illustrated in FIG. 14A.

The light-emitting diode 306 is also referred to as a luminous thin-film component composed of semiconducting materials and is designed for generating electromagnetic radiation (e.g. light), e.g. if an electric current for operating the optoelectronic component 1400a flows through the functional layer structure 312 between the first electrode 310 and the second electrode 314. The electromagnetic radiation generated can be emitted at least through some layers and parts of the optoelectronic component 1400a and away from the optoelectronic component 1400a. In other words, the optoelectronic component 1400a can be configured for converting electrical energy into electromagnetic radiation (e.g. light), i.e. act as a light source.

The first electrode 310 (also referred to as bottom electrode 310 or as bottom contact) and/or the second electrode 314 (also referred to as top electrode or as top contact) can be formed in such a way that they include at least one layer. The first electrode 310 and/or the second electrode 314 can be formed in such a way that they have a layer thickness in a range of approximately 1 nm to approximately 50 nm, for example of less than or equal to approximately 40 nm, for example of less than or equal to approximately 20 nm, for example of less than or equal to approximately 10 nm.

The first electrode 310 is formed from an electrically conductive substance. The first electrode 310 is formed as an anode, that is to say as a hole-injecting electrode. The first electrode 310 is formed in such a way that it includes a first electrical contact pad (not illustrated), wherein a first electrical potential (provided by an energy source (not illustrated), for example a current source or a voltage source) can be applied to the first electrical contact pad. Alternatively, the first electrode 310 can be electrically conductively connected to a first electrical contact pad for the purpose of applying a first potential. The first electrical contact pad (also referred to as contacting surface) can be designed for electrically conductive contacting, e.g. for bonding or soldering. The first electrical potential can be the ground potential or some other predefined reference potential.

The functional layer structure 312 is formed on or above the first electrode 310. The functional layer structure 312 may include an emitter layer 318, for example including or composed of fluorescent and/or phosphorescent emitter materials.

The second electrode 314 is formed on or above the functional layer structure 312. The second electrode 314 is formed as a cathode, that is to say as an electron-injecting electrode. The second electrode 314 includes a second electrical terminal (in other words a second electrical contact pad) for applying a second electrical potential (which is different than the first electrical potential), provided by the energy source. Alternatively, the second electrode 314 can be electrically conductively connected to a second electrical contact pad for the purpose of applying a second potential. The second electrical contact pad can be designed for electrically conductive contacting, e.g. for bonding or soldering. The second electrical potential can be a potential different than the first electrical potential.

Alternatively or additionally, an electrical contact pad may include a plurality of electrical contact pads.

For the purpose of operating the optoelectronic component 1400a, i.e. if the optoelectronic component 1400a is intended to generate electromagnetic radiation (i.e. in an on state of the optoelectronic component 1400a), the first electrical potential and the second electrical potential can be generated by the energy source (e.g. a current source, e.g. a power supply unit or a driver circuit) and can be applied to the first electrical contact pad and the second electrical contact pad. The first electrical potential and the second electrical potential can bring about an electric current that flows through the functional layer structure 312 and excites the latter for generating and emitting electromagnetic radiation.

The second electrical potential has a value such that the difference with respect to the first electrical potential (in other words the operating voltage of the optoelectronic component 1400a that is applied to the optoelectronic component 1400a) has a value in a range of approximately 1.5 V to approximately 20 V, for example a value in a range of approximately 2.5 V to approximately 15 V, for example a value in a range of approximately 3 V to approximately 12 V. The energy source can be designed for generating this operating voltage.

The substrate 302 can be provided as an integral substrate 302. The substrate 302 can be in the form of a monolithic substrate or a substrate constructed integrally from a plurality of layers, wherein the plurality of layers are fixedly connected to one another.

The substrate 302 can have various shapes. By way of example, the substrate 302 can be formed as a film (e.g. a metallic film or a plastics film, e.g. PE films), as a plate (e.g. a plastics plate, a glass plate or a metal plate). Alternatively or additionally, the substrate 302 can be formed such that it is prism-shaped, trapezoidal, cylindrical, or pyramidal. Alternatively or additionally, the substrate 302 can have at least one flat or at least one curved surface, e.g. a main processing surface on a main processing side of the substrate 302, on or above which the layers of the optoelectronic component 1400a are formed.

The substrate 302 may include or be formed from an electrically insulating substance. An electrically insulating substance may include one or a plurality of the following materials: a plastic or a composite material (e.g. a laminate composed of a plurality of films or a fiber-plastic composite).

A plastic includes or is formed from one or a plurality of polyolefins (for example high or low density polyethylene (PE) or polypropylene (PP)). Furthermore, the plastic may include or be formed from polyvinyl chloride (PVC), polystyrene (PS), polyester and/or polycarbonate (PC), polyethylene terephthalate (PET), polyethersulfone (PES) and/or polyethylene naphthalate (PEN). Alternatively or additionally, the substrate 302 can be formed in such a way that it includes one or a plurality of the substances mentioned above.

Alternatively or additionally, the substrate 302 may include or be formed from an electrically conductive substance, e.g. an electrically conductive polymer, a metal (e.g. aluminum or steel), a transition metal oxide or an electrically conductive transparent oxide.

In accordance with various embodiments, the substrate 302 can be electrically conductive. For this purpose, the substrate 302 may include or be formed from an electrically conductive substance or include or be formed from an electrically insulating substance that is coated with an electrically conductive substance. The electrically conductive coating may include or be formed from an electrically conductive substance, e.g. metal (i.e. in the form of a metallic coating).

By way of example, a substrate 302 including or formed from a metal can be formed as a metal film or a metal-coated film. The substrate 302 can be designed in such a way that it conducts electric current during the operation of the optoelectronic component 1400a.

If the substrate 302 is electrically conductive, then the substrate 302 can serve as an electrode, e.g. as a bottom electrode 310, of the light-emitting diode 306. Alternatively or additionally, the substrate 302 can be formed from a substance having a high thermal conductivity or may include such a substance.

Alternatively or additionally, the substrate 302 can be formed as light-transmissive, e.g. opaque, translucent or even transparent, with respect to at least one wavelength range of the electromagnetic radiation, for example in at least one range of visible light, for example in a wavelength range of approximately 380 nm to 780 nm.

If the substrate 302 is formed as light-transmissive, generated light can be emitted through the substrate 302. In this case, the optoelectronic component 1400a is formed as a rear-side emissive light source, as a so-called bottom emitter, and the surface of the substrate 302 that faces away from the functional layer structure 312 can form a light emission surface of the optoelectronic component 1400a. If a first electrode 310 is used for a bottom emitter, it can likewise be formed as light-transmissive.

If the substrate 302 is formed as light-nontransmissive, the second electrode 314 can be formed as light-transmissive. Generated light can then be emitted through the second electrode 314. In this case, the optoelectronic component 1400a is formed as a front-side emissive light source, as a so-called top emitter, and the surface of the second electrode 314 that faces away from the functional layer structure 312 can form the light-emission surface of the optoelectronic component 1400a.

Alternatively or additionally, the substrate 302 can be designed as light-reflecting, e.g. can be a part of a mirror structure or form the same. What can thus be achieved is that the luminous efficiency can be increased.

In accordance with various embodiments, the optoelectronic component 1400a can be formed as a transparent component, i.e. as a combination of top emitter and bottom emitter. In the case of a transparent component, both the first electrode 310 and the second electrode 310 can be formed as transparent.

The first electrode 310 can be formed from or include a metal. In the case where the first electrode 310 includes or is formed from a metal, the first electrode 310 can have a layer thickness in a range of approximately 10 nm to approximately 25 nm, for example in a range of approximately 10 nm to approximately 18 nm, for example in a range of approximately 15 nm to approximately 18 nm.

In order to form the first electrode 310 such that it is light-transmissive, the first electrode 310 may include or be formed from a transparent conductive oxide (TCO). Transparent conductive oxides are transparent conductive substances, for example metal oxides, such as, for example, zinc oxide, tin oxide, cadmium oxide, titanium oxide, indium oxide, or indium tin oxide (ITO). Alongside binary metal-oxygen compounds, such as, for example, ZnO, SnO₂, or In₂O₃, ternary metal-oxygen compounds, such as, for example, AlZnO, Zn₂SnO₄, CdSnO₃, ZnSnO₃, MgIn₂O₄, GaInO₃, Zn₂In₂O₅ or In₄Sn₃O₁₂, or mixtures of different transparent conductive oxides also belong to the group of TCOs. Furthermore, the TCOs do not necessarily correspond to a stoichiometric composition and can furthermore be p-doped or n-doped, or hole-conducting (p-TCO) or electron-conducting (n-TCO).

Furthermore, for the case where the first electrode 310 includes or is formed from a transparent conductive oxide (TCO), the first electrode 310 can have for example a layer thickness in a range of approximately 50 nm to approximately 500 nm, for example a layer thickness in a range of approximately 75 nm to approximately 250 nm, for example a layer thickness in a range of approximately 100 nm to approximately 150 nm.

Alternatively or additionally, the first electrode 310 may include or be formed from an electrically conductive polymer.

Alternatively or additionally, the first electrode 310 can be formed by a layer stack or a combination of the layers described above. One example is a silver layer applied on or above an indium tin oxide layer (ITO) (Ag on ITO) or ITO-Ag-ITO multilayers. Alternatively or additionally, the first electrode 310 may include or be formed from a layer stack of a plurality of layers of the same metal or of different metals and/or of the same TCO or of different TCOs.

The second electrode 314 can be formed as an anode, that is to say as a hole-injecting electrode. The second electrode 314 can be formed in accordance with one or a plurality of the above-described embodiments of the first electrode 310, e.g. identically to, similarly to or differently than the first electrode 310.

FIG. 14B illustrates a schematic cross-sectional view or side view of an optoelectronic component 1400b in accordance with various embodiments. A description is given below of the layer construction for the optoelectronic component 1400b which is formed in the form of an organic optoelectronic component, i.e. includes an optically functional layer structure 312 formed from organic layers. To put it another way, the optoelectronic component 1400b can be formed as an organic light source. The optoelectronic component 1400b illustrated in FIG. 14B can for example largely correspond to the optoelectronic component 1400a illustrated in FIG. 14a.

Forming the organic functional layer structure 312 may include forming one or a plurality of emitter layers 318. A plurality of emitter layers 318 can be formed for example identically to one another or differently than one another.

Alternatively or additionally, the emitter layer 118 may include or be formed from organic polymers, organic oligomers, organic monomers, organic small, non-polymeric molecules (“small molecules”) or a combination of these materials.

Alternatively or additionally, the emitter materials can be embedded in a matrix material, e.g. a plastic, in a suitable manner. It should be pointed out that other suitable emitter materials can likewise be provided. Alternatively or additionally, the emitter materials of the emitter layer(s) 318 of the optoelectronic component 1400b can be chosen for example such that the optoelectronic component 1400b emits white light. Alternatively or additionally, the emitter layer(s) 318 includes/include a plurality of emitter materials emitting in different colors (for example blue and yellow or blue, green and red); alternatively, the emitter layer(s) 318 is/are also constructed from a plurality of partial layers, such as a blue fluorescent emitter layer 318 or blue phosphorescent emitter layer 318, a green phosphorescent emitter layer 318 and/or a red phosphorescent emitter layer 318. The mixing of the different colors can result in the emission of light having a white color impression. Alternatively, provision is made for arranging a converter material in the beam path (i.e. in the light-propagation region) of the primary emission generated by these layers, which converter material at least partly absorbs the primary radiation and emits a secondary radiation having a different wavelength, such that a white color impression results from a (not yet white) primary radiation as a result of the combination of primary radiation and secondary radiation.

The first electrode 310 is formed on or above the substrate 302. A hole injection layer is formed (not shown) on or above the first electrode 310. A hole transport layer 316 (also referred to as a hole conducting layer 316) is formed on or above the hole injection layer. Furthermore, the emitter layer 318 is formed on or above the hole transport layer 316. An electron transport layer 320 (also referred to as electron conducting layer 320) is formed on or above the emitter layer 318. An electron injection layer (not shown) is formed on or above the electron transport layer 320. The second electrode 314 is formed on or above the electron injection layer.

The layer sequence of the optoelectronic component 1400b is not restricted to the exemplary embodiments described above; by way of example, one or a plurality of the layers mentioned above can be omitted. Furthermore, alternatively, the layer sequence can be formed in the opposite order. Furthermore, two layers can be formed as a layer.

The hole injection layer can be formed in such a way that it has a layer thickness in a range of approximately 10 nm to approximately 1000 nm, for example in a range of approximately 30 nm to approximately 300 nm, for example in a range of approximately 50 nm to approximately 200 nm.

Alternatively or additionally, the optoelectronic component 1400b may include a plurality of hole injection layers.

The hole transport layer 316 can be formed in such a way that it has a layer thickness in a range of approximately 5 nm to approximately 50 nm, for example in a range of approximately 10 nm to approximately 30 nm, for example approximately 20 nm.

Alternatively or additionally, the optoelectronic component 1400b may include a plurality of hole transport layers 316.

The electron transport layer 320 can be formed in such a way that it has a layer thickness in a range of approximately 5 nm to approximately 50 nm, for example in a range of approximately 10 nm to approximately 30 nm, for example approximately 20 nm.

Alternatively or additionally, the optoelectronic component 1400b may include a plurality of electron transport layers 320.

The electron injection layer can be formed in such a way that it has a layer thickness in a range of approximately 5 nm to approximately 200 nm, for example in a range of approximately 20 nm to approximately 50 nm, for example approximately 30 nm.

Alternatively or additionally, the optoelectronic component 1400b may include a plurality of electron injection layers.

Alternatively or additionally, the optoelectronic component 1400b can be formed in such a way that it includes two or more organic functional layer structures 312, e.g. a first organic functional layer structure 312 (also referred to as first organic functional layer structure units) and a second organic functional layer structure 312 (also referred to as second organic functional layer structure units).

The second organic functional layer structure unit can be formed above or alongside the first functional layer structure unit. An intermediate layer structure (not shown) can be formed between the organic functional layer structure units.

The intermediate layer structure can be formed as an intermediate electrode, for example in accordance with one of the configurations of the first electrode 310. An intermediate electrode can be electrically connected to an external energy source. The external energy source can provide a third electrical potential at the intermediate electrode. However, the intermediate electrode can also have no external electrical connection, for example by virtue of the intermediate electrode having a floating electrical potential.

Alternatively or additionally, the intermediate layer structure can be formed as a charge generation layer (CGL) structure. A charge generation layer structure includes or is formed from one or a plurality of electron-conducting charge generation layer(s) and one or a plurality of hole-conducting charge generation layer(s). The electron-conducting charge generation layer(s) and the hole-conducting charge generation layer(s) are formed in each case from an intrinsically conducting substance or a dopant in a matrix. The charge generation layer structure should be formed with respect to the energy levels of the electron-conducting charge generation layer(s) and the hole-conducting charge generation layer(s) in such a way that electron and hole can be separated at the interface between an electron-conducting charge generation layer and a hole-conducting charge generation layer. Optionally, the charge generation layer structure can have a diffusion barrier between adjacent layers.

Alternatively or additionally, the abovementioned layers can be formed as mixtures of two or more of the abovementioned layers.

It should be pointed out that, alternatively or additionally, one or a plurality of the abovementioned layers arranged between the first electrode 310 and the second electrode 314 is/are optional.

By way of example, the organic functional layer structure 312 can be formed as a stack of two, three or four OLED units arranged directly one above the other. In this case, the organic functional layer structure 312 has a layer thickness of a maximum of approximately 3 μm.

In addition, the optoelectronic component 1400b can be formed in such a way that it optionally includes further organic functional layers (which can consist of organic functional materials), for example arranged on or above the one or the plurality of emitter layers 318 or on or above the electron transport layer(s) 216, which serve to further improve the functionality and thus the efficiency of the optoelectronic component 1400b.

FIG. 14C illustrates a schematic cross-sectional view or side view of an optoelectronic component 1400c in accordance with various embodiments, which for example largely corresponds to the exemplary embodiment illustrated in FIG. 14B. As an alternative to the layer sequence illustrated in FIG. 14B, the optoelectronic component 1400c may include the layer sequence illustrated in FIG. 14C, which layer sequence is described below.

A barrier layer 304 is arranged on or above the substrate 302 and between the substrate 302 and the light-emitting diode 306. The substrate 302 and the barrier layer 304 form a hermetically impermeable substrate 302. The barrier layer 304 may include or be formed from one or a plurality of the following substances: aluminum oxide, zinc oxide, zirconium oxide, titanium oxide, hafnium oxide, tantalum oxide, lanthanum oxide, silicon oxide, silicon nitride, silicon oxynitride, indium tin oxide, indium zinc oxide, aluminum-doped zinc oxide, poly(p-phenylene terephthalamide), nylon 66, and mixtures and alloys thereof.

In accordance with various embodiments, the barrier layer 304 can be formed for example from an electrically insulating substance (i.e. as an electrical insulator, as a so-called insulation layer).

The barrier layer 304 can be formed in such a way that it has a layer thickness of approximately 0.1 nm (one atomic layer) to approximately 1000 nm, for example a layer thickness of approximately 10 nm to approximately 100 nm in accordance with one configuration, for example approximately 40 nm in accordance with one configuration.

The barrier layer 304 can be formed by means of vacuum processing, liquid phase processing or alternatively by means of other suitable deposition methods.

Alternatively or additionally, the barrier layer 304 can be formed in such a way that it includes a plurality of partial layers. In the case of a barrier layer 304 including a plurality of partial layers, all the partial layers can be formed e.g. by means of an atomic layer deposition method. A layer sequence including only ALD layers can also be referred to as a “nanolaminate”.

Alternatively or additionally, the barrier layer 304 is formed in such a way that it includes one or a plurality of optically high refractive index materials, for example one or a plurality of material(s) having a high refractive index, for example having a refractive index of at least 2.

Alternatively or additionally, the abovementioned layers are formed as mixtures of two or more of the abovementioned layers.

Alternatively or additionally, one of the optoelectronic components described herein may include a color filter and/or a converter structure, which can be arranged and/or formed above the substrate 302. By means of targeted variation of a surface in the case of planar substrates 302 (variation of the bottom contact 310 or single-sided coating or application of a color filter or of a converter), it is possible to achieve a targeted change in the emission in one direction, independently of the emission in the other direction. This applies to nontransparent and (semi)transparent embodiments.

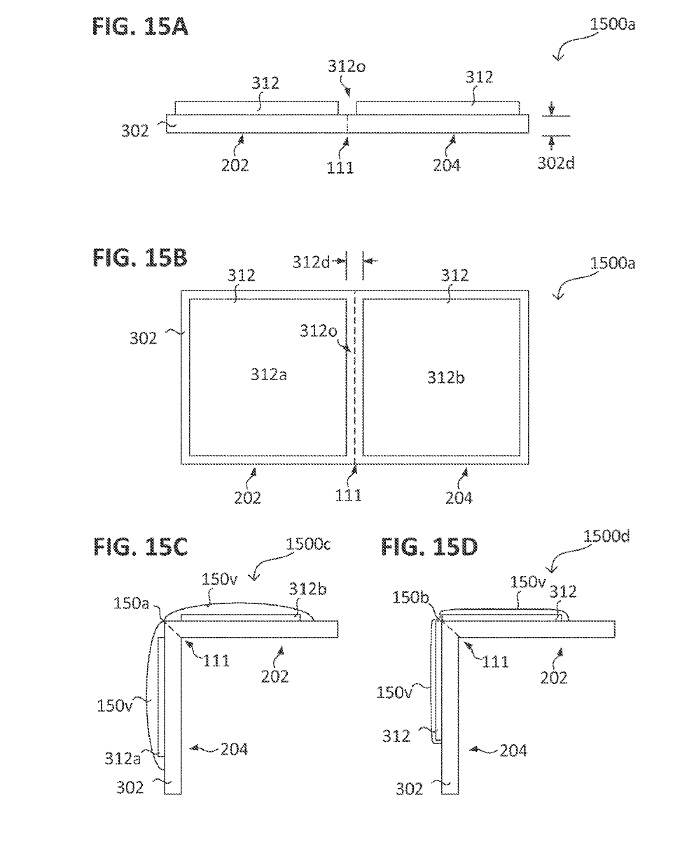

FIG. 15A to FIG. 15D illustrate in each case an optoelectronic component 1500a, 1500c, 1500d in accordance with various embodiments in a method in accordance with various embodiments for producing an optoelectronic component.

The features of the optoelectronic components 1500a, 1500c, 1500d illustrated in FIG. 15A to FIG. 15D can be understood as an alternative or in addition to the features of the optoelectronic components as described hereinabove and can be part of a lighting device, for example.

FIG. 15A illustrates a schematic cross-sectional view or side view of an optoelectronic component 1500a in accordance with various embodiments, and FIG. 15B shows the optoelectronic component 1500a in a schematic plan view or side view.

The optoelectronic component 1500a may include a carrier 302 and an optically functional layer structure 312. The rear side of the carrier 302 (that side of the carrier 302 which faces away from the optically functional layer structure 312) can be exposed, such that illustratively a bending radius 511r that is as small as possible (cf. FIG. 5B) can be achieved. Alternatively or additionally, the carrier 302 can be coated with an optically functional layer structure 312 on both sides.

The carrier 302 can furthermore be exposed above the desired bending region 111, e.g. by a cutout 312o being formed in the optically functional layer structure 312. What is thus achieved is that the desired bending region 111 can be bent, without the optically functional layer structure 312 being mechanically loaded, which can damage the latter. By way of example, the optically functional layer structure 312 can remain planar during the bending of the desired bending region 111. Consequently, even brittle materials can be used for forming the optically functional layer structure 312 or an electrode 310, 314.

The exposed region of the carrier 302 can divide the optically functional layer structure 312 into a first segment 312a of the optically functional layer structure 312 (also referred to as first optoelectronic component unit 312b) and a second segment 312b of the optically functional layer structure 312 (also referred to as second optoelectronic component unit 312b), which are arranged at the distance 312d from one another.

The first optoelectronic component unit 312a can be part of the first body network segment 202 and the second optoelectronic component unit 312b can be part of the second body network segment 204. Analogously thereto, the optoelectronic component 1500a may include further optoelectronic component units that are arranged at a distance 312d from one another.

The smaller the bending radius 511r (cf. FIG. 5B) with which the carrier 302 is bent in the desired bending region 111, the smaller the distance 312d between the optoelectronic component units 312a, 312b can be configured. What can thus be achieved is that virtually no non-luminous edge (e.g. as a result of a gap between the tiles in the joining region) remains and the impression of a seamlessly luminous 3D body is more realistic.

Furthermore, the optoelectronic component 1500a may include one or a plurality of metalization layers (not illustrated) which extend(s) e.g. over the desired bending region 111 and electrically connect(s) the segments 312a, 312b—separated from one another by the cutout 312o—of the optically functional layer structure 312 to one another. The metalization layers can for example in each case electrically contact an electrode 310, 314 of the optoelectronic component 1500a. Each metalization layer may include one or a plurality of conductor tracks which electrically connect(s) at least two electrodes 310, 314 to one another.

By means of the method in accordance with various embodiments, e.g. as described above, after the luminous surfaces have been formed, they can already be driven in 2D (i.e. before the body network is bent). In this case, subsequent electrical connection of the luminous surfaces is not necessary.

The substrate 302 can have a thickness 302d. The thickness 302d of the substrate 302 can be correspondingly adapted to the required radius of curvature. If e.g. a smaller radius of curvature is required, a substrate 302 having a smaller thickness 302d can be chosen. The thinner the substrate 302 (i.e. the smaller the thickness 302d thereof), the lower the loading capacity thereof can be. Therefore, for very thin substrates 302 it may be necessary for these to be applied to a suitable main body for stabilization after bending. The main body can have for example a shape which is assigned to the body network, i.e. analogously to the body to which the body network is assigned.

FIG. 15C and FIG. 15D illustrate in each case a schematic cross-sectional view or side view of an optoelectronic component in accordance with various embodiments in a method in accordance with various embodiments for producing an optoelectronic component.

The optoelectronic component 1500c illustrated in FIG. 15C includes an encapsulation 150v, which is formed above the first optoelectronic component unit 312a and the second optoelectronic component unit 312b and extends completely over the first optoelectronic component unit 312a and the second optoelectronic component unit 312b and completely covers them. The first optoelectronic component unit 312a and the second optoelectronic component unit 312b can be part of the optically functional layer structure 312 formed in accordance with a body network, as described above.

In the encapsulation 150v, a cutout 150a, e.g. in the form of a groove, can be formed above the desired bending region 111, such that the encapsulation 150v is configured to be thinner above the desired bending region 111 than above the optically functional layer structure 312. Alternatively, it is possible to form the cutout 150a of the encapsulation 150v above the desired bending region 111 in the form of a through opening, such that the carrier 302 is freed of the encapsulation 150v above the desired bending region 111. The cutout 150a can be formed for example by the removal of part of the encapsulation 150v above the desired bending region 111, e.g. by means of etching.

What can thus be achieved is that the optoelectronic component 1500c can bend more easily in the desired bending region 111, since the encapsulation 150v has a reduced stiffening effect.

After the encapsulation 150v has been formed above the optically functional layer structure 312, the body network can be bent. In this case, it is possible to form the cutout 150a in the encapsulation 150v in such a way that it is possible to avoid damage to the encapsulation 150v as a result of the bending in the desired bending region 111. Consequently, the optically functional layer structure 312 can be sufficiently protected by the encapsulation 150v, e.g. against environmental influences, such as moisture or solvent, for instance.

By way of example, a material of the encapsulation 150v can be sufficiently elastic or have a sufficiently high yield point, such that damage can be avoided.

The thinner the substrate 302, the less the encapsulation 150v can be stressed, i.e. extended, during bending. In other words, the neutral axis, i.e. the plane whose length does not change during bending, can be displaced in the direction of the encapsulation 150v, which reduces the extension thereof as a result of the bending.

In accordance with various embodiments, the substrate 302 can have a thickness 302d in a range of approximately 10 μm to approximately 1 mm, e.g. in a range of approximately 20 μm to approximately 0.5 mm, e.g. in a range of approximately 30 μm to approximately 0.2 mm, e.g. in a range of approximately 50 μm to approximately 0.1 mm, e.g. less than approximately 0.5 mm.

In accordance with various embodiments, the distance 312d can have a value in a range of approximately 50 μm to approximately 500 μm, e.g. in a range of approximately 100 μm to approximately 200 μm, e.g. less than approximately 200 μm.

In accordance with various embodiments, an optoelectronic component unit 312a, 312b can have a cross-sectional area in a range of approximately 1 mm² to approximately 1000 cm² (in other words provide a light-emission area), e.g. in a range of approximately 10 mm² to approximately 100 cm², e.g. in a range of approximately 100 mm² to approximately 10 cm². The optoelectronic component 1500d illustrated in FIG. 15D includes an encapsulation 150v, which is formed above the first optoelectronic component unit 312a and the second optoelectronic component unit 312b and extends completely over the first optoelectronic component unit 312a and the second optoelectronic component unit 312b and completely covers them.

As an alternative to the optoelectronic component 1500c illustrated in FIG. 15C, the encapsulation 150v can be formed with a desired breaking location above the desired bending region 111. The desired breaking location can be required for example if an elastic deformation of the encapsulation 150v is too small to prevent damage to the encapsulation 150v during the bending of the body network.

The desired breaking location can be formed for example by means of a cutout 150a in the encapsulation 150v or the encapsulation 150v can advantageously break above the desired bending region 111 as a result of the mechanical loading during bending, for example as a result of the direct contact with the desired bending region 111.

The desired breaking location can enable a defined severing (e.g. cracking or breaking) of the encapsulation 150v above the desired bending region 111. This makes it possible for example to prevent a crack from propagating in the encapsulation 150v in an uncontrolled manner, e.g. as far as toward the optically functional layer structure 312, and impairing the protective effect of the encapsulation 150v, since moisture, for example, can propagate in the crack right into the optically functional layer structure 312.

Illustratively, a trench 150b can be formed in the encapsulation 150v as a result of the bending, which trench completely or partly penetrates through the encapsulation 150v.

Illustratively, although the encapsulation 150v may have been damaged after bending, it is nevertheless leaktight. In this case, the distance 312d can be dimensioned with a magnitude such that the damage to the encapsulation 150v is correspondingly taken into account. In other words, the cutout 312o can serve as a buffer region, which enables a functional optoelectronic component 1500d after bending.

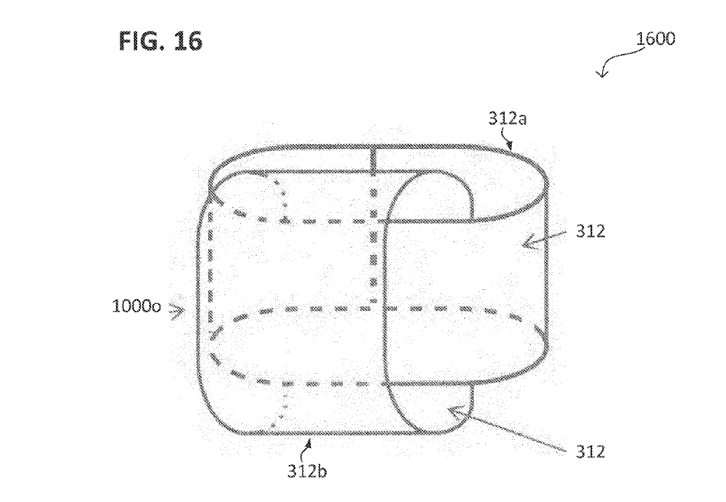

FIG. 16 illustrates a schematic perspective view of an optoelectronic component 1600 in accordance with various embodiments in a method in accordance with various embodiments for producing an optoelectronic component.

In accordance with various embodiments, complex 3D bodies can be realized by folding and cutting, such as the optoelectronic component 1600 illustrated in FIG. 16, for example. By way of example, the first optoelectronic component unit 312a and the second optoelectronic component unit 312b can be folded into one another and/or onto one another. Illustratively, they can serve as oval displays.

The first optoelectronic component unit 312a can be oriented in such a way that it emits light outward, and the second optoelectronic component unit 312b can be oriented in such a way that it emits light inward.

It should be noted that the optoelectronic component units 312a, 312b are not necessarily closed upon themselves. In other words, the oval display area can alternatively or additionally be formed in an open fashion and/or delimit e.g. a through opening 1000o from which the light emitted inward emerges.

While the disclosed embodiments have been particularly shown and described with reference to specific embodiments, it should be understood by those skilled in the art that various changes in form and detail may be made therein without departing from the spirit and scope of the disclosed embodiments as defined by the appended claims. The scope of the disclosed embodiments is thus indicated by the appended claims and all changes which come within the meaning and range of equivalency of the claims are therefore intended to be embraced.

1. A method for producing an optoelectronic component, the method comprising:
forming an optically functional layer structure in accordance with at least one part of a geometric network of a body, wherein the part of the geometric network comprises at least one desired bending region;
bending the part of the geometric network in the at least one desired bending region, such that at least one part of the body is formed.

2. The method as claimed in claim 1,
wherein the optically functional layer structure is formed on a continuous elastic carrier; and wherein the method further comprises:
severing the carrier at least partly along a path in accordance with the part of the geometric network, wherein the path surrounds the part of the geometric network.

3. The method as claimed in claim 1,
wherein the part of the geometric network is bent in such a way that at least two marginal regions of the part of the geometric network which do not have a shared desired bending region are joined together, such that they adjoin one another.

4. The method as claimed in claim 3,
wherein the part of the geometric network is bent in such a way that the two marginal regions of the part of the geometric network joined together form an edge of the body.

5. The method as claimed in claim 1,
wherein the part of the geometric network alongside the at least one desired bending region is bent in such a way that at least one curved outer surface of the part of the body is formed.

6. The method as claimed in claim 1, further comprising:
forming a metallization layer which electrically contacts the optically functional layer structure and which comprises exposed contact regions; and
forming an encapsulation above the optically functional layer structure.

7. The method as claimed in claim 1,
wherein forming the optically functional layer structure is effected in such a way that the optically functional layer structure is cut out along the at least one desired bending region ROHM, such that the desired bending region is free of the optically functional layer structure.

8. The method as claimed in claim 7,
wherein the optically functional layer structure is cut out by a part of the optically functional layer structure above the at least one desired bending region being removed.

9. The method as claimed in claim 1,
wherein the at least one desired bending region is bent in such a way that it has a bending radius of less than approximately 5 mm.

10. The method as claimed in claim 9,
wherein the at least one desired bending region is bent in such a way that it forms an edge of the part of the body.

11. The method as claimed in claim 8,
wherein the at least one desired bending region remains spring-elastically deformable after the bending of the part of the geometric network.

12. An optoelectronic component comprising:
an optically functional layer structure formed in accordance with at least one part of a geometric network of a body, wherein the part of the geometric network comprises at least one desired bending region;
wherein the part of the geometric network is bent in the at least one desired bending region in such a way that at least one part of the body is formed.

13. (canceled)

14. An optoelectronic component comprising:
a carrier;
an optically functional layer structure arranged above the carrier, wherein the carrier comprises a plurality of desired bending regions which are free of the optically functional layer structure;
wherein the carrier is bent with a bending radius of less than approximately 5 mm in at least the plurality of desired bending regions.

15. The method as claimed in claim 1,
wherein the optically functional layer structure is formed on a continuous elastic carrier;
wherein the at least one part of the geometric network of the body comprises at least an edge;
wherein forming the optically functional layer structure is effected in such a way that the optically functional layer structure is cut out along the at least one desired bending region, such that the desired bending region is free of the optically functional layer structure; and
wherein the at least one desired bending region forms the at least one edge of the body.

16. The method as claimed in claim 6,
wherein the metallization layer and/or the encapsulation extend partly or completely over the at least one desired bending region.

17. The method as claimed in claim 1,
wherein the optically functional layer structure comprises two structure segments, which adjoin the at least one desired bending region and are arranged at a distance from one another;
wherein the distance has a value in a range of approximately 50 μm to approximately 500 μm.

18. The optoelectronic component as claimed in claim 12,
wherein the optoelectronic component further comprises a continuous elastic carrier;
wherein the optically functional layer structure is formed in accordance with at least one part of a geometric network of a body, which comprises at least an edge, on the continuous elastic carrier;
wherein the optically functional layer structure is cut out along the at least one desired bending region, such that the desired bending region is free of the optically functional layer structure; and
wherein the at least one desired bending region forms the at least one edge of the body.

19. The method as claimed in claim 14,
wherein the optically functional layer structure is cut out along the at least one desired bending region, such that the desired bending region is free of the optically functional layer structure.

20. The method as claimed in claim 15,
wherein the part of the geometric network is bent in such a way that the two marginal regions of the part of the geometric network joined together form the at least one edge or an additional edge of the body.
